(19) United States
(12) Patent Application Publication
(10) Pub. No.: US 2018/0301266 A1
(43) Pub. Date: Oct. 18, 2018

(54) MAGNETIC STRUCTURES HAVING DUSTING LAYER

(71) Applicant: Cornell University, Ithaca, NY (US)

(72) Inventors: Yongxi Ou, Ithaca, NY (US); Robert A. Buhrman, Ithaca, NY (US); Daniel C. Ralph, Ithaca, NY (US)

(21) Appl. No.: 15/955,248

(22) Filed: Apr. 17, 2018

Related U.S. Application Data
(60) Provisional application No. 62/486,434, filed on Apr. 17, 2017.

(51) Int. Cl. H01F 10/32; H01L 43/02; H01L 43/08; H01L 43/10; H01L 43/12; G11C 11/16

(52) U.S. Cl. CPC H01F 10/329; H01F 10/3286; H01F 10/3259; H01L 43/02; H03K 19/18; H01L 43/10; H01L 43/12; G11C 11/161; H01L 43/08

(57) ABSTRACT

A device implemented based on the disclosed technology includes a thin-film magnetic structure that includes a substrate and thin film layers formed over the substrate to include a ferromagnetic layer formed over the substrate, and a non-magnetic dusting layer in contact with the ferromagnetic layer and structured to have a thickness around one molecular layer to enhance an interfacial perpendicular magnetic anisotropy energy density of the ferromagnetic layer.

### PRIORITY CLAIMS AND RELATED PATENT APPLICATIONS

This patent document claims the priority and benefits of U.S. Provisional Application No. 62/486,434 entitled “STRONG PERPENDICULAR MAGNETIC ANISOTROPY ENERGY DENSITY AT FE ALLOY/HFO2 INTERFACES” and filed on Apr. 17, 2017. The entirety of the above application is incorporated by reference as part of the disclosure of this patent document.

### STATEMENT REGARDING FEDERALLY SPONSORED RESEARCH OR DEVELOPMENT

This invention was made with government support by the Office of Naval Research (ONR) and by the National Science Foundation grant NSF/MRSEC (DMR-1120296) through the Cornell Center for Materials Research (CCMR), and by NSF through use of the Cornell Nanofabrication Facility (CNF)/NINN (ECCS-1542081) and the CCMR facilities. The government has certain rights in the invention.

### TECHNICAL FIELD

This patent document relates to circuits and devices having magnetic materials or structures based on electron spin torque effects and their applications, including non-volatile magnetic memory circuits, non-volatile logic devices, and spin-torque excited nanomagnet oscillators.

### BACKGROUND

Electrons and other charged particles possess spin as one of their intrinsic particle properties and such a spin is associated with a spin angular momentum. A spin of an electron has two distinctive spin states. Electrons in an electrical current may be unpolarized by having equal probabilities in the two spin states. The electrons in an electrical current are spin polarized by having more electrons in one spin state than electrons in the other spin state. A spin-polarized current can be achieved by manipulating the spin population via various methods, e.g., by passing the current through a magnetic layer having a particular magnetization. Alternatively, a pure spin current that involves no net transport of electron charge can be created by the spin Hall effect in certain heavy metal layers including, but not limited to, Pt, certain Pt alloys, or highly resistive W (beta-phase W), and highly resistive Ta (beta-phase Ta), or by strong spin-orbit interactions at the interface between such heavy metals and a ferromagnetic metal layer. In various magnetic microstructures, a spin-polarized current can be directed into a magnetic layer to cause transfer of the angular momenta of the spin-polarized electrons to the magnetic layer and this transfer can lead to exertion of a spin-transfer torque (STT) on the local magnetic moments in the magnetic layer and precession of the magnetic moments in the magnetic layer. Under a proper condition, this spin-transfer torque can cause a flip or switch of the direction of the magnetization of the magnetic layer, or cause the displacement of a non-uniform magnetic configuration in the ferromagnetic layer that has local areas of chiral spin texture, or under controlled conditions cause the magnetic structure in the magnetic layer to be excited and thus undergo precession at microwave frequencies around the effective magnetic field seen by the structure.

### SUMMARY

The technology disclosed in this document provides significant enhancement of the magnetic anisotropy properties of thin-film magnetic structures utilized in circuits and devices based on electron spin transfer torque effects and their applications, including non-volatile magnetic memory circuits, non-volatile logic devices, and spin-torque excited nanomagnet oscillators.

The technology disclosed in this document also provides thin-film magnetic structures where a magnetic layer has a magnetization direction that is substantially perpendicular to the magnetic layer, i.e., exhibiting perpendicular magnetic anisotropy (PMA), due to an interfacial perpendicular magnetic anisotropy energy density Kₛ that arises from spin-orbit coupling effects in the electronic bonds that form at the interface between the thin magnetic material and, in the unenhanced case, an adjacent magnesium oxide (MgO) layer.

The technology disclosed here also provides enhancement of the magnetic anisotropy properties of thin-film magnetic structures in cases where a magnetic layer has in-plane magnetic anisotropy but has a sufficiently strong Kₛ due to, in the unenhanced case, the same interfacial spin-orbit coupling effect with an adjacent MgO layer that the magnetic field for rotating the magnetization of the magnetic layer from an equilibrium orientation that is in-plane, i.e. parallel to the plane of the thin-film layer, to an orientation perpendicular to the thin film plane is greater than zero but substantially reduced from the larger value, 4πMₛ, required without that interfacial magnetic anisotropy energy density (Mₛ is the saturation magnetization of the magnetic layer).

In some implementations, a device implemented based on the disclosed technology includes a thin-film magnetic structure that includes a substrate and thin film layers formed over the substrate to include a ferromagnetic layer formed over the substrate, and a non-magnetic dusting layer in contact with the ferromagnetic layer and structured to have a thickness around one molecular layer to enhance an interfacial perpendicular magnetic anisotropy energy density of the ferromagnetic layer.

In some implementations, a device implemented includes a thin-film magnetic structure that includes a substrate and thin film layers formed over the substrate to include a magnetic layer formed over the substrate, and a non-magnetic dusting layer including a metal oxide of a thickness ranging from less than an atom or molecule in average coverage to one atom or molecule, or somewhat more, in average coverage disposed immediately adjacent to the magnetic layer to enhance an interfacial magnetic anisotropy energy density of the ferromagnetic layer.

In some implementations, a method of fabricating a magnetic structure includes forming, over a substrate, a conductive base layer comprising a conductor material, forming, over the conductive base layer, a magnetic layer, depositing, over the magnetic layer, a metal layer of a thickness ranging from less than one atom in average coverage to one or somewhat more than one atom in average coverage immediately adjacent to the magnetic layer, and forming, over the metal layer, an insulating oxide layer. Here, the metal layer turns into a non-magnetic dusting layer via oxidation of the metal layer before or during the formation of the insulating oxide layer by exposure to oxygen ions or molecules.

In some implementations, such a magnetic layer is part of a thin-film magnetic structure with other thin film layers formed over a substrate and the material structure of other layers in such a thin-film magnetic structure can be used to influence the PMA property of the magnetic layer. Therefore, in addition to selecting or engineering of the material composition of the magnetic layer itself, the surrounding material structure of the magnetic layer in the thin-film magnetic structure can be designed to enhance the PMA property of the magnetic layer.

In some implementations, a device in accordance with the disclosed technology includes a thin-film magnetic structure that includes a substrate and thin film layers formed over the substrate. The thin film layers include a metal layer formed over the substrate, a ferromagnetic layer formed over the metal layer to exhibit perpendicular magnetic anisotropy (PMA) by having a magnetization direction perpendicular to the magnetic layer, an oxide layer formed over the magnetic layer, and a non-magnetic dusting layer including a metal oxide formed between the magnetic layer and the oxide layer to enhance the PMA of the magnetic layer. The thin film layers may further include a spacer layer disposed between the metal layer and the ferromagnetic layer.

In some implementations, a magnetic tunnel junction (MTJ) device in accordance with the disclosed technology includes an electrically conductive channel layer generating a spin current in response to an in-plane charge current, a free magnetic layer formed over the conductive channel layer and switching a magnetization direction thereof in response to the spin current, a fixed magnetic layer formed over the free magnetic layer and having a fixed magnetization direction, an insulating barrier layer formed between the free magnetic layer and the fixed magnetic layer, and a non-magnetic dusting layer including a metal oxide disposed at an interface between the insulating barrier layer and the free magnetic layer. The MTJ device may further include a spacer layer disposed between the electrically conductive channel layer and the free magnetic layer.

In some implementations, a method of fabricating a magnetic structure includes forming, over a substrate, a conductive base layer comprising a conductor material, forming, over the conductive base layer, a free magnetic layer, forming, over the free magnetic layer dusting layer material of average coverage of less than one atomic layer or up to one or somewhat more than one atomic layer in average coverage, as required for a particular implementation, and forming, over the less than one or up to one atomic layer or slightly more than one atomic layer of dusting layer material, an insulating layer through a radio frequency (RF) sputtering deposition, or by some other deposition method. Here, the less than one, one or slightly more than one atomic layer of dusting layer material is oxidized, during the RF sputtering deposition of the insulating layer, or by other process, to form a dusting layer.

The above and other aspects and features, and exemplary implementations and applications, are described in greater detail in drawings, the description and the claims.

### BRIEF DESCRIPTION OF DRAWINGS

FIGS. 1(a) and 1(b) show examples of thin-film magnetic structures implemented based on the disclosed technology.

FIG. 2 shows an example of a magnetic structure where a bottom ferromagnetic layer has perpendicular magnetic anisotropy and chiral spin texture enhanced by a metal-oxide dusting layer.

FIGS. 3(a) and 3(b) show results of x-ray photoelectron spectroscopy (XPS) measurements on an as-grown Ta(6)/FeCoB(1.2)/HfO₂(0.2)/MgO/Ta and Ta(6)/FeCoB(1.3)/MgO/Ta magnetic multilayer stack.

FIG. 4 shows a plot of the effective demagnetization field 4πM_{eff} of a 1.8 nm FeCoB layer as a function of Hf metal dusting thickness

FIGS. 5(a) and 5(b) illustrate example thin-film magnetic structure in accordance with some embodiments of the disclosed technology.

FIG. 6(a) illustrates an example thin-film magnetic structure including a HfO2 dusting layer, FIG. 6(b) illustrates another example thin-film magnetic structure including a TaOx dusting layer, and FIG. 6(c) illustrates another example thin-film magnetic structure that does not include any dusting layer.

FIG. 7(a) shows vibrating sample magnetometry (VSM) measurements of magnetization, FIG. 7(b) shows the effective anisotropy energy density K_{eff} determined from anomalous Hall measurements as a function of in-plane magnetic field, FIG. 7(c) shows anomalous Hall measurements as a function of out-of-plane magnetic field, for the as-grown samples Ta(6)/FeCoB(t_{FeCoB})/HfO₂(0.2)/MgO/Ta and Ta(6)/FeCoB(t_{FeCoB})/TaOₓ(0.2)/MgO/Ta, and FIG. 7(d) shows the perpendicular anisotropy fields of Ta(6)/FeCoB(0.8)/HfO₂(t_{Hf})/MgO/Ta samples as deposited and after different post-fabrication annealing treatments.

FIG. 8(a) shows the perpendicular anisotropy fields of (a) beta-W(4)/FeCoB(0.8)/HfO₂(t_{Hf})/MgO/Ta, FIG. 8(b) illustrates (b) the perpendicular anisotropy fields of Ta/alpha-W(4)/FeCoB(0.8)/HfO₂(t_{Hf})/MgO/Ta after different post-fabrication annealing treatments, FIG. 8(c) illustrates anomalous Hall measurements of the as-grown samples Ta(6)/NiFe(1.4)/HfO₂(0.2)/MgO/Ta and Ta(6)/Hf(0.5)/NiFe(1.5)/HfO₂(0.2)/MgO/Ta as a function of in-plane magnetic field, and FIG. 8(d) illustrates the perpendicular anisotropy fields of MgO(1.6)/FeCoB(t_{FeCoB})/HfO₂(0.3)/MgO(0.8)/Ta samples after different post-fabrication annealing treatments.

FIG. 9(a) shows the result of the use of a ZrO₂ dusting layer on the as-grown perpendicular magnetic anisotropy field Hₐ (in units of Tesla) as a function of the thickness of the FeCoB layer that is dusted with 0.2 nm of Zr. FIG. 9(b) shows the effective perpendicular magnetic anisotropy energy density as a function of the FeCoB thickness for the same samples as in (a).

FIG. 10 provides a comparison of the as-grown magnetic anisotropy behavior obtained with HfO₂ dusting and obtained with ZrO₂ dusting.

FIG. 11 shows the variation of the effective magnetic anisotropy energy density, K_{eff} as a function of the effective thickness of the FeCoB; that is after subtraction of the small thickness of a magnetic dead layer.

FIG. 12 shows a Hf-spacer-Hf-dusting sample structure and measurement schematics along with a SEM image showing an example elliptical nano-pillar MTJ on top of a W SHE channel after it has been defined by electron-beam lithography and argon ion milling.

FIG. 13(a) shows current-induced switching loop of the MTJ free layer showing a thermally assisted switching current, along with an inset showing an in-plane field-switching minor loop of the free layer. FIG. 13(b) shows current ramp rate measurement on the device of FIG. 13(a). FIG. 13(c) shows the free layer effective demagnetization field change with annealing temperature for a Hf-spacer-Hf-dusting sample compared to that of a Hf-dusting-only sample and a sample without Hf insertion as measured by flip-chip ferromagnetic resonance (FMR). FIG. 13(d) shows linewidths at different resonance frequencies for the Hf-dusting-only sample and the Hf-spacer-Hf-dusting sample measured by flip-chip FMR.

FIGS. 14(a)-14(c) show fast and reliable pulse switching of a Hf-spacer-Hf-dusting sample.

FIGS. 15(a) and 15(b) show the annealing temperature dependence of the Hf-dusting effect, including (a) flip-chip FMR measurement on two Hf-dusting-only samples annealed at 240° C. and 300° C., respectively, showing a further reduction of Meff at higher annealing temperature, and (b) current-induced switching of Hf-dusting-only samples annealed at two different temperatures, 240° C. and 300° C.

FIG. 16 shows an example of a magnetic tunneling junction (MTJ) device structure including a conductive channel layer with a dusting layer disposed between an insulating barrier layer and a free magnetic layer.

FIG. 17 shows another example of an MTJ device structure including a combination of a dusting layer at an interface between an insulating barrier layer and a free magnetic layer and a spacer layer at an interface between the free magnetic layer and a conductive channel layer

FIGS. 18(a)-18(c) show an example fabrication method of a magnetic structure in accordance with some implementations of the disclosed technology.

### DETAILED DESCRIPTION

The disclosed technology in this patent document combines selecting/engineering of the material composition of a magnetic layer and the engineering of the surrounding material structure of the magnetic layer in the thin-film magnetic structure to enhance the perpendicular magnetic anisotropy (PMA) of the magnetic layer in the thin-film magnetic structure. The specific examples provided in this document demonstrate that a non-magnetic dusting layer comprising a monolayer or approximately monolayer thickness of a metal oxide can be formed next to the PMA magnetic layer in the thin-film magnetic structure to enhance the PMA of the magnetic layer when compared to the same thin-film magnetic structure without the non-magnetic dusting layer.

In an implementation of the disclosed technology, a ferromagnetic layer exhibits the perpendicular magnetic anisotropy (PMA) having a magnetization direction that is substantially perpendicular to the magnetic layer due to an interfacial magnetic anisotropy energy density (Ks) that arises from spin-orbit coupling effects in the electronic bonds that form at the interface between the thin magnetic material and, in an unenhanced case, an adjacent magnesium oxide (MgO) layer. In the unenhanced case, the electronic bonds between the Fe ion component in the ferromagnetic layer and the oxygen ions at the surface of the MgO layer are considered the most important ones for this spin-orbit coupling effect.

In a magnetic structure where the magnetic layer exhibits PMA, under the spin transfer torque (STT) mechanism, a spin-polarized current, or alternatively a pure spin current, can be directed into a magnetic layer to cause transfer of the angular momenta of the spin-polarized electrons to the magnetic layer to cause switching of the direction of the magnetization of the magnetic layer in two opposite directions that are perpendicular to the magnetic layer. Alternatively, a pure spin current can cause the displacement of a non-uniform magnetic configuration in the ferromagnetic layer that exhibits PMA on average but that has localized areas of chiral spin texture.

In another implementation of the disclosed technology, a magnetic layer has in-plane magnetic anisotropy but has a sufficiently strong interfacial magnetic anisotropy energy density (Ks) due to, in the unenhanced case, the same interfacial spin-orbit coupling effect with an adjacent MgO layer. The magnetic field for rotating the magnetization of the magnetic layer from an equilibrium orientation that is in-plane, i.e. parallel to the plane of the thin-film layer, to an orientation perpendicular to the thin film plane is greater than zero but substantially reduced from a larger value (e.g., 4πMₛ) required without that interfacial magnetic anisotropy energy density (Mₛ is the saturation magnetization of the magnetic layer), and the reduced field for obtaining a magnetic orientation perpendicular to the thin film plane is referred to as 47πM_{eff}, or the effective demagnetization field.

In a magnetic structure where the magnetization of the magnetic layer has an in-plane anisotropy, under the STT mechanism a spin-polarized current, or alternatively a pure spin current, can be directed into the magnetic layer to cause transfer of the angular momenta of the spin-polarized electrons to the magnetic layer to cause switching, via a STT process that moves the magnetic moment temporarily out of the plane of the film, of the direction of the magnetization of the magnetic layer between two opposite, but more or less collinear, directions that are also largely collinear to the magnetic layer. These collinear directions are determined by the geometrical anisotropy, or shape, of the patterned magnetic layer, or by some other in-plane anisotropy effect. Alternatively, a spin-polarized current or pure spin current can cause under controlled conditions the magnetic structure in the magnetic layer to be excited and thus undergo precession at microwave frequencies around the effective magnetic field seen by the structure.

In both the PMA and in-plane magnetic anisotropy cases, for improved performance of magnetic devices that utilize spin transfer torque effects in some implementations of the disclosed technology, including those that employ the spin Hall and other spin-orbit torque effects, it is beneficial to enhance the interfacial magnetic anisotropy energy density (Ks) beyond that which can be generated by the electronic bonds between the magnetic layer and an adjacent MgO layer. Some embodiments of the disclosed technology obtain a high value of Ks in combination with the use of ferromagnetic materials containing Fe other than solely those that consist of combinations of Fe with Co and B, e.g. with the use of FeCo, FeB, FeNi, or other ferromagnetic material, including other Fe binary, and Fe tertiary alloys and compounds that include Fe as a component.

Various embodiments of this patent document disclose the selection/engineering of the composition of a very thin layer of material immediately surrounding the magnetic layer in the thin-film magnetic structure that has the effect to substantially enhance the interfacial magnetic anisotropy energy density (Kₛ) affecting the magnetic layer in comparison to what can be obtained in magnetic thin film structures that do not include the embodiment. Specifically, an embodiment of the disclosed technology utilizes a non-magnetic dusting layer comprising the oxide of an appropriate metal having specific qualities but with the atomic number of the metal always greater than twenty, and whose average layer thickness can range from much less than one monolayer up to approximately one monolayer, or slightly more, or equivalently an oxide thickness ranging between 0.05 or approximately 0.3 nanometers (nm) in thickness. In other words, from dusting oxide coverage that can be varied as appropriate for the implementation from less than a complete monolayer up to a coverage that is on average one monolayer or slightly more in thickness. An embodiment of the disclosed technology includes forming or otherwise inserting such a dusting layer between the magnetic layer and the adjacent MgO layer in the thin-film magnetic structure. As the result the interfacial magnetic anisotropy energy density (Kₛ) experienced by the magnetic layer is substantially enhanced in comparison to that of the same thin-film magnetic structure without the addition of this specific type of non-magnetic dusting layer located at the interface of the magnetic layer with MgO, or with some other adjacent material. In some embodiments of the disclosed technology, the non-magnetic dusting layer can be comprised of a metal oxide including but not limited to hafnium oxide (HfO₂), zirconium oxide (ZrO₂), titanium oxide, (TiO₂), yttrium oxide (Y₂O₃), certain rare earth oxides, or any other stable metal oxide that can formed through exposure of the metal to oxygen at or near room temperature, and with a standard enthalpy of formation similar in magnitude or greater than that of HfO₂ but always greater than the magnitude of the standard enthalpy of formation of MgO, and always with atomic number of the metal that is oxidized to form the oxide greater than twenty. In the describing specific examples of the disclosed technology, the chemical formula of a metal oxide may be provided to explain some specific metal oxide composition as an example. Metal oxide material combinations that are different from the precise combination of metal and oxygen as indicated by a stoichiometric formula in the described examples may be used for implementing the disclosed technology. For example, in a dusting layer formed by hafnium oxide HfO₂, the actual ratio of O to Hf in the formed oxide dusting layer may also be somewhat less than or somewhat more than two.

In an embodiment of the disclosed technology, the thin non-magnetic metal oxide dusting layer can be formed by depositing up to a monolayer or slightly more of the un-oxidized metal onto the top of the ferromagnetic layer and then oxidizing this metal dusting layer into metal oxide by exposure to oxygen ions or molecules either before or during the subsequent deposition of MgO via a standard sputtering or other type of MgO deposition step. In another embodiment of the disclosed technology where MgO is not needed for the particular implementation, the metal dusting layer can be oxidized by controlled exposure of the surface of the metal dusted ferromagnetic layer to oxygen by some other means before deposition of a protective capping layer, which can be a thicker layer of the dusting metal oxide or some other material. The enhanced interfacial magnetic anisotropy energy density that results can achieve a strong PMA, or alternatively a reduced demagnetization field (4πM_{eff}) without any high temperature post-fabrication annealing treatment. Annealing treatment of the magnetic structure after formation of the non-magnetic dusting layer can further enhance the interfacial magnetic anisotropy energy density.

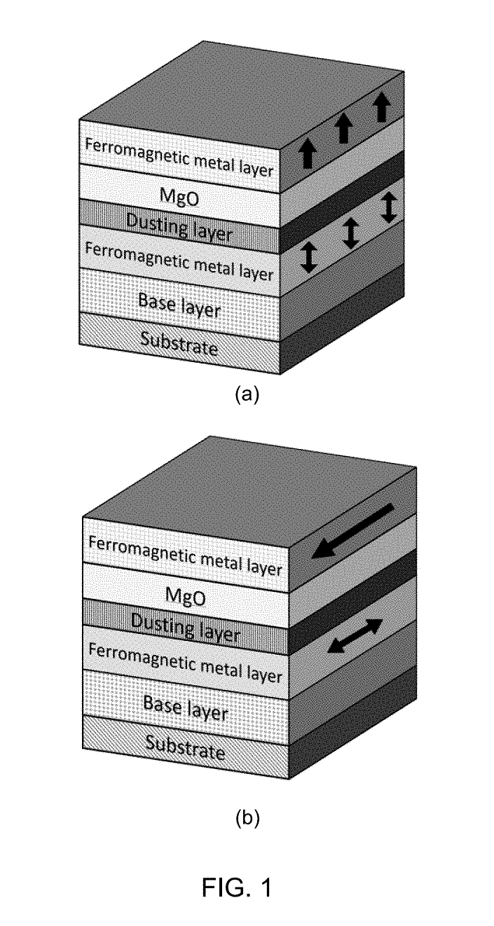

FIG. 1 shows schematic illustrations of two examples in FIGS. 1(a) and 1(b) based on the disclosed technology for thin-film magnetic structures including a non-magnetic dusting layer comprising a metal oxide of less than or approximately one monolayer in thickness formed next to the ferromagnetic layer and then capped by MgO insulator layer that is sufficiently thin to form a magnetic tunnel junction (MTJ) barrier which allows quantum mechanical tunneling of electrons from and to the top ferromagnetic layer which is pinned in collinear direction to the dusted ferromagnetic layer that serves as a magnetic free layer (FL). In FIG. 1(a) of FIG. 1, the magnetization of the ferromagnetic layers is oriented perpendicular to the plane of the ferromagnetic layers, as indicated by the arrows, which are bi-directional for the FL. In FIG. 1(b) of FIG. 1, the magnetization of the ferromagnetic layers is oriented parallel to the plane of the ferromagnetic layers, as indicated by the arrows, which are bi-directional for the FL.

In some embodiments of the disclosed technology, a thin-film multilayer structure with metal-oxide dusting enhanced interfacial magnetic anisotropy properties can be implemented in various structures and devices based on spin-transfer torque (STT) effect including STT magnetoresistive random access memory (MRAM) circuits and devices, and also STT magnetoresistive random access memory (MRAM) and logic circuits and devices that utilize spin currents generated by the spin Hall effect, or by other mechanisms, for operation. For example, such STT effects can reversibly switch the magnetic orientation of a ferromagnetic thin film layer, or reversibly displace a non-uniform magnetic structure along the in-plane direction of a ferromagnetic thin film layer, or excite a nanomagnet's magnetic moment into steady microwave precession. The enhanced interfacial magnetic anisotropy enabled by this technology can increase the strength of the perpendicular magnetic anisotropy (PMA) of a ferromagnetic thin film layer in a device structure whose magnetic moment is intended to be oriented perpendicular to the plane of the layer. The enhanced interfacial magnetic anisotropy can also controllably reduce the demagnetization field property (e.g., 4πM_{eff}) of a ferromagnetic thin film layer in a device structure whose magnetic moment is intended to be oriented parallel to the plane of the layer.

In an MRAM device and circuit a switchable ferromagnetic material is sometimes referred to as a free magnetic layer (FL). This FL can have PMA and then the magnetization of the FL can be reversed in the out-of-plane direction by a spin-polarized current, or by an incident spin current, above a certain threshold. This FL can alternatively have an in-plane magnetic orientation at equilibrium that can be reversed between two preferred in-plane directions by an incident spin current.

For example, a STT-MRAM circuit can include a magnetic tunnel junction (MTJ) as a magnetoresistive element formed of two or more thin film ferromagnetic layers or electrodes, which are usually referred to as the free magnetic layer (FL) having a magnetic moment whose magnetic orientation direction can be switched or changed and the pinned magnetic layer (PL) whose magnetic moment is fixed in direction. The free magnetic layer (FL) and the pinned magnetic layer (PL) are separated by an insulating barrier layer (e.g., a MgO layer) that is sufficiently thin to allow electrons to transit through the barrier layer via quantum mechanical tunneling when an electrical bias voltage is applied between the electrodes as shown in FIG. 1. The electrical resistance across the MTJ depends upon the relative magnetic orientations of the PL and FL layers. The magnetic moment of the FL can be switched between two stable orientations in the FL. The resistance across the MTJ exhibits two different values under the two relative magnetic orientations of the PL and FL layers, which can be used to represent two binary states “1” and “0” for binary data storage, or, alternatively, for binary logic applications. The magnetoresistance of this element is used to read out this binary information from the memory or logic cell. In some device implementations, the FL layer can be used to form spin-torque excited nanomagnet oscillators.

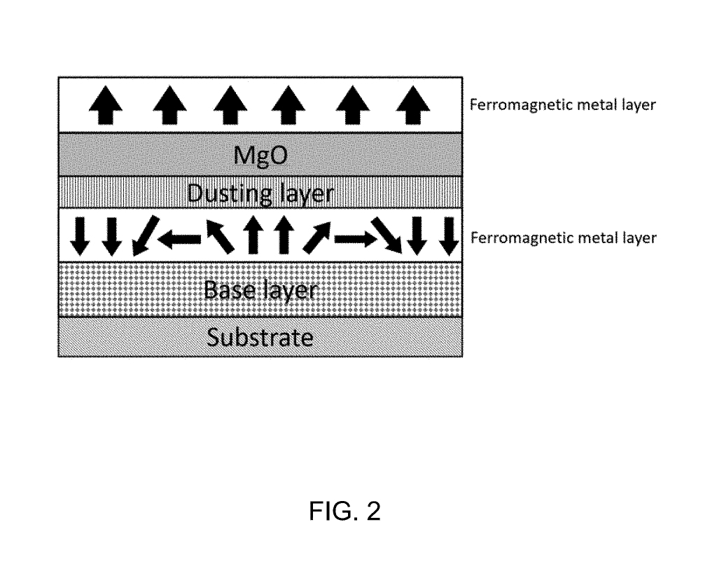

FIG. 2 shows a schematic illustration of a magnetic structure where the bottom ferromagnetic layer has perpendicular magnetic anisotropy enhanced by a metal-oxide dusting layer and also has localized regions of non-uniform chiral domain wall structure as indicated by the arrows. Vertical spin currents generated by a lateral electronic current in the base layer can controllably drive the lateral displacement of the domain walls.

A strong interfacial magnetic anisotropy energy density (Kₛ) can be used to achieve the robust perpendicular magnetic anisotropy (PMA) in heavy metal (HM)/ferromagnet (FM)/oxide thin-film heterostructures that is essential for the implementation of ultra-high density memory elements based on the spin transfer torque (STT) switching of perpendicularly magnetized tunnel junctions (MTJs). A strong interfacial magnetic anisotropy energy density Kₛ can also be used to create the perpendicularly magnetized nanowire structures needed to enable manipulation of domain walls with chiral symmetry and of novel magnetic chiral structures such as skyrmions by the spin Hall effect, as shown in FIG. 2. A strong Kₛ provides the capability for adjusting the effective demagnetization field (4πM_{eff}) of the thin in-plane magnetized free layers in three-terminal spin Hall devices to sufficiently low values, of the order of 0.1 to 0.4 Tesla (1000-4000 Oe), so that the spin torque switching current, which in that device implementation scales directly with the effective demagnetization field (4πM_{eff}), can be reduced to levels compatible with integration with Si electronics.

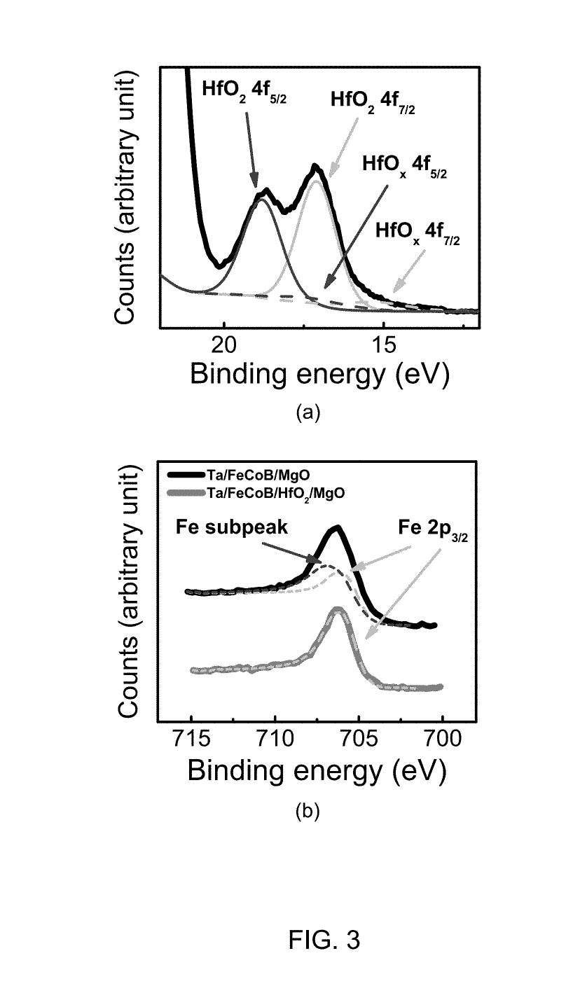

FIGS. 3(a) and 3(b) show results of x-ray photoelectron spectroscopy (XPS) measurements on an as-grown Ta(6)/FeCoB(1.2)/HfO₂(0.2)/MgO/Ta and Ta(6)/FeCoB(1.3)/MgO/Ta magnetic multilayer stack. The numbers in parentheses are the thicknesses of the layer components in nm. In FIG. 3(a), the HfO₂ 4f_{7/2} and 4f_{5/2} electron energy level peaks are clearly displayed at 17.1 eV and 18.8 eV, with only a very small peak at about 16.0 eV indicating a small amount of less than fully oxidized Hf. There is no evidence of an un-oxidized Hf metal 4f_{7/2} peak at 14.3 eV. To achieve strong PMA it is also desirable that the Fe alloy not be oxidized beyond the interfacial Fe—O bonds. FIG. 3(b) shows for the same sample the XPS 2p_{3/2} peak of Fe at 706.0 eV, which can be well fit with the narrow asymmetric spin-split peak function characteristic of metallic Fe. For a sample without the Hf dusting layer, the upper plot in FIG. 3(b), the Fe 2p_{3/2} peak is much broader with a high energy tail indicative of substantial, detrimental, oxidation of the surface Fe during the direct deposition of MgO by radio frequency (RF) sputtering.

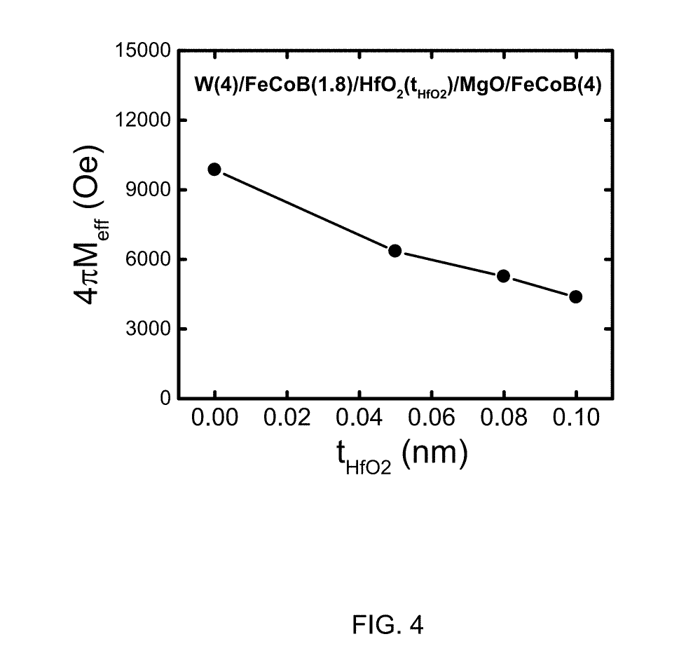

FIG. 4 shows a plot of the effective demagnetization field 47πM_{eff} of a 1.8 nm FeCoB layer as a function of Hf metal dusting thickness, i.e. the thickness of the Hf that is deposited prior to its oxidation during the subsequent deposition of MgO. All the samples were annealed at 240° C. The plot shows that the demagnetization field varies quasi-linearly with Hf metal dusting and hence can be readily controlled by dusting.

Table 1 below shows selected examples of the interfacial perpendicular magnetic anisotropy energy density (Kₛ) for different material systems with the HfO₂ dusting technique as obtained for the as-grown and annealed cases as indicated. In the case of the NiFe ferromagnetic layer (third row) the composition is approximately 80% Ni and 20% Fe. In the case of the third and fourth rows, a 0.5 nm Hf spacer is inserted above the base metal layer, Ta in row 3 and Pt in row 4, to accommodate the lattice structure mismatch between the base layer crystal structure and the ferromagnetic layer crystal structure. This reduces thin film strain that would otherwise degrade the benefit of the HfO₂ dusting layer above the ferromagnetic layer.

TABLE 1
examples of the interfacial perpendicular
magnetic anisotropy energy density as obtained with
HfO₂ dusting (rows 1-8) and with ZrO₂ dusting (rows 9-11)

| | | Kₛ |
|---|---|---|
| Systems | Conditions | (erg/cm²) |
| Ta(6 nm)/FeCoB/MgO | As-grown | 0.30 |
| Ta(6 nm)/FeCoB/HfO₂(0.2 nm)/ | As-grown | 1.74 |
| MgO | | |
| Ta(6 nm)/Hf(0.5 nm)/FeNi/ | As-grown | 0.80 |
| HfO₂(0.2 nm)/MgO | | |
| Ta(1 nm)/Pt(4 nm)/Hf(0.5 nm)/ | Annealed at 300 C. for 1 h | 0.70 |
| FeCoB/HfO₂(0.2 nm)/MgO | | |
| W(4 nm)/FeCoB/HfO₂(0.1 nm)/ | As-grown | 1.04 |
| MgO | | |
| W(4 nm)/FeCoB/HfO₂(0.1 nm)/ | Annealed at 240 C. for 1 h | 0.94 |
| MgO | | |
| W(4 nm)/FeCoB/HfO₂(0.1 nm)/ | Annealed at 300 C. for 1 h | 1.80 |
| MgO | | |
| W(4 nm)/FeCoB/HfO₂(0.1 nm)/ | Annealed at 420 C. for 1 h | 1.49 |
| MgO | | |
| W(4 nm)/FeCoB/ZrO₂(0.2 nm)/ | Annealed at 335 C. for 1 h | 0.62 |
| MgO | | |
| W(4 nm)/FeCoB/ZrO₂(0.2 nm)/ | Annealed at 400 C. for 1 h | 0.94 |
| MgO | | |
| W(4 nm)/FeCoB/ZrO₂(0.2 nm)/ | Annealed at 450 C. for 1 h | 1.49 |
| MgO | | |

The magnetic structure implemented based on an embodiment of the disclosed technology may include FM/oxide combination that yields the strong interfacial magnetic energy density desirable for practical devices is FeₓCo_{y}B_{z} (FeCoB)/MgO, with typically x≥0.4. There the strong interfacial perpendicular magnetic anisotropy energy density (Kₛ) originates from the strong spin-orbit interaction in the hybridized 3d Fe-2p O bonding at the FeCoB/MgO interface. Even there obtaining significant PMA requires an annealing step that can compromise the layers in the magnetic heterostructure, and the PMA is not as strong as is optimum, while for STT devices with in-plane magnetization of the FL the ability to easily and controllably tune the demagnetization field is lacking.

In some embodiments of the disclosed technology, a significant enhancement in the interfacial perpendicular magnetic anisotropy energy density (Kₛ) of a ferromagnetic layer containing Fe as a component in a thin film multilayer structure is created by forming a non-magnetic metal-oxide dusting layer comprising of up to a monolayer of coverage, or slightly more, or equivalently of as little as 0.05 nm to as much as 0.3 nm, or slightly more, in thickness, of one of certain effective metal oxides immediately adjacent to the ferromagnetic layer. This non-magnetic metal-oxide dusting layer enables stronger perpendicular magnetic anisotropy (PMA), or alternatively enables the controllable reduction of the effective demagnetization field (4πM_{eff}) of a ferromagnetic layer that has in-plane magnetic anisotropy. In an embodiment of the disclosed technology, the thin-film magnetic multilayer structure may include a ferromagnetic metal layer comprising any ferromagnetic material that includes Fe as a component, including FeCoB, FeCo, FeB, FeNi, etc., as well as tertiary alloys and compounds for which Fe is a component. The thin-film magnetic multilayer structure may also include a non-magnetic dusting layer comprising a metal oxide such as hafnium oxide (HfO₂), zirconium oxide (ZrO₂), titanium oxide, (TiO₂), yttrium oxide (Y₂O₃), rare earth oxides, or a stable metal oxide with a standard enthalpy of formation similar in magnitude or greater than HfO₂ but always greater than the magnitude of the standard enthalpy of formation of MgO. In some implementations, for the above thin film multilayer structure to exhibit both strong PMA and strong tunneling magnetoresistance effect, the thin-film magnetic multilayer structure may also include a thin capping layer (for example, as in FIG. 1(a)) such as MgO and a top, pinned magnetic layer whose orientation is fixed in place, and where the MgO layer is sufficiently thin to allow electrons to transit through the barrier layer via quantum mechanical tunneling. For implementations where the magnetic structure has an in-plane magnetic orientation, for the above thin film multilayer structure to exhibit both a reduced demagnetization field and a strong tunneling magnetoresistance effect, the magnetic structure may also include a thin capping layer (for example, as in FIG. 1(b)) such as MgO and a top, pinned magnetic layer whose orientation is fixed in place, and where the MgO layer is sufficiently thin to allow electrons to transit through the barrier layer via quantum mechanical tunneling.

In an embodiment of the disclosed technology, the thin non-magnetic metal oxide dusting layer can be formed by depositing up to a monolayer or slightly more of the un-oxidized metal onto the top of the ferromagnetic layer and then converting this metal dusting layer into a metal-oxide dusting by exposure to oxygen ions or molecules either before or during the subsequent deposition of MgO via a standard sputtering step. In another embodiment of the disclosed technology, if MgO is not needed for the particular implementation, then the metal dusting layer can be oxidized by controlled exposure of the surface of the metal dusted ferromagnetic layer to oxygen by some other means before deposition of a protective capping layer (not shown in the drawings), which can be a thicker layer of the dusting metal oxide or some other material. The enhanced interfacial magnetic anisotropy energy density that results in high PMA, or alternatively a reduced demagnetization field (4πM_{eff}) can be achieved without any high temperature post-fabrication annealing treatment. Selected examples from experiments that have demonstrated the effectiveness of this oxide dusting technique are provided in Table 1. For example, without the HfO₂ dusting the as-grown sample as shown in row 1 of the Table is only 0.3 ergs/cm². With the HfO₂ dusting the as-grown result as shown in row 2 of the Table is 1.74 ergs/cm², which is an exceptionally high value for any as-grown structure utilizing FeCoB and an MgO capping layer. This result is achieved because the standard enthalpy of formation of the metal oxide is comparable to or higher in magnitude than that for the formation of any Fe oxide, and thus provides a significant degree of protection of the Fe from deleterious oxidation during the deposition of the MgO or other insulating or conducting capping layer. As an example, the full oxidation of a 0.2 nm Hf metal dusting layer and the resultant HfO₂ provides the protection to the Fe at the top of the ferromagnetic layer from oxidation during the MgO deposition, as demonstrated by the x-ray photoemission spectroscopy data shown in FIG. 3. The annealing treatment can further enhance the interfacial magnetic anisotropy energy density, and hence further enhance the PMA, as further illustrated by selected results reported in Table 1. Alternatively, for samples where the ferromagnetic layer is sufficiently thick that it has its magnetization in the plane of the layers, thermal annealing of a metal-oxide dusted layer can systematically reduce the demagnetization field (4πM_{eff}).

The enhanced thin film multilayer structure can be used as an element of various devices, including a magnetic device, a magnetic cell, a random access memory, a spin-transfer-torque magnetic memory, a magnetic memory elements based on chiral domain wall structures or on magnetic skyrmions, for such as racetrack magnetic memory and logic devices or magnetic based microwave oscillators that are excited by spin transfer torque.

The interfacial magnetic anisotropy energy density that is obtained between transition metal ferromagnetic material and MgO may be understood as being caused by the spin-split hybridization of the orbital bonds between Fe and O, or in particular from the Fe—O—Mg bonds. This hybridization may be used to interpret the enhanced interfacial magnetic anisotropy energy density in the disclosed technology based on Hf dusting layers for the case of Fe—O—Hf bonding. The enhanced interfacial perpendicular magnetic anisotropy energy density (Kₛ) obtained with the metal-oxide dusting layer may be due to the role of the metal ion (e.g., Hf), or due to the fact that there is a higher density of O in the HfO₂ material than in the MgO case, and hence more beneficial O—Fe bonds are possible at the interface.

As shown in FIG. 1 and Table 1, MgO may be disposed on top of the oxidized Hf to enable the structure to exhibit a strong tunneling magnetoresistance effect. In other implementations, the Hf dust can be deposited on top of the ferromagnet and then oxidized without oxidizing the underlying material. Other oxides could be utilized this way, without the MgO capping layer in the above example.

Depending on the choice of the heavy metal (HM) that is placed underneath the ferromagnetic layer in a spin torque magnetic tunnel junction device, or in a device that utilizes spin current to drive the lateral displacement of non-uniform magnetic structure in the ferromagnetic layer, the magnetic structure may be annealed to at least 400° C. which can provide compatibility with Si microelectronics processing.

This metal oxide dusting technique not only improves the perpendicular magnetic anisotropy properties of thin film FeCoB/MgO structures as needed for various device implementations but also allows for PMA devices to be made from the low-damping, low-magnetostriction alloy permalloy (Ni₈₀Fe₂₀) and other NiFe alloys. This result is illustrated in Table 1 where the experimental result is reported from the measurement of the interfacial magnetic anisotropy energy density of a NiFe layer that has a 0.2 nm HfO₂ dusting oxide layer between it and a capping MgO layer, and also has a thin Hf metal spacer layer placed between the bottom of the NiFe layer and an underlying Ta base layer. The Hf metal spacer accommodates the crystalline lattice mismatch between the Ta and the NiFe. This high level of strength of interfacial magnetic anisotropy energy density, and resulting PMA, has not been reported for Ni₈₀Fe₂₀ or similar alloys prior to the work for the disclosed technology. This technology therefore can be implemented in ways to substantially expand the options for engineering magnetic thin film multilayer structures for spintronics.

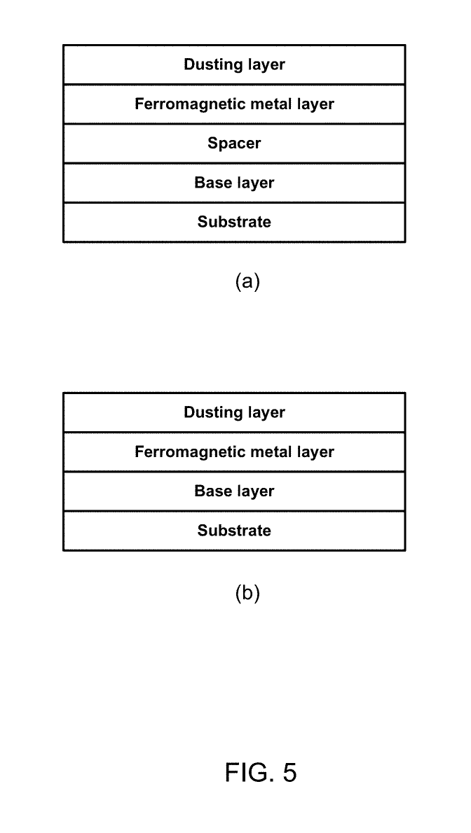

FIGS. 5(a) and 5(b) illustrate example thin-film magnetic structures including a non-magnetic dusting layer comprising a metal oxide formed next to the PMA magnetic layer. The disclosed enhanced PMA thin-film structure can be implemented in various structures and devices based on spin-transfer torque (STT) effect including STT magnetoresistive random access memory (MRAM) circuits and devices. The disclosed thin-film magnetic structure including a combination of a magnetic layer (e.g., PMA magnetic layer) and an adjacent non-magnetic dusting layer comprising a metal oxide can be used as a composite switchable ferromagnetic material with enhanced PMA, sometimes referred to as a free magnetic layer (FL) because the PMA magnetization can be changed by a spin-polarized current above a certain threshold.

For example, an STT-MRAM circuit can include a magnetic tunnel junction (MTJ) as a magnetoresistive element formed of two or more thin film ferromagnetic layers or electrodes, which are usually referred to as the free magnetic layer (FL) having a magnetic moment whose magnetic orientation direction can be switched or changed, and a pinned magnetic layer (PL) whose magnetic moment is fixed in direction. The free magnetic layer (FL) and the pinned magnetic layer (PL) are separated by an insulating barrier layer (e.g., a MgO layer) that is sufficiently thin to allow electrons to transit through the barrier layer via quantum mechanical tunneling when an electrical bias voltage is applied between the electrodes. The electrical resistance across the MTJ depends upon the relative magnetic orientations of the PL and FL layers. The magnetic moment of the FL can be switched between two stable orientations in the FL. The resistance across the MTJ exhibits two different values under the two relative magnetic orientations of the PL and FL layers, which can be used to represent two binary states “1” and “0” for binary data storage, or, alternatively, for binary logic applications. The magnetoresistance of this element is used to read out this binary information from the memory or logic cell. In some device implementations, the FL layer can be used to form spin-torque excited nanomagnet oscillators.

The PMA behavior of heavy metal (HM)/Fe alloy/MgO thin film heterostructures can be enhanced by inserting an ultrathin HfO₂ passivation layer between the Fe alloy and the MgO. This may be accomplished by depositing one to two atomic layers of Hf onto the Fe alloy before a subsequent radio frequency (RF) sputtering deposition of the MgO layer. This Hf layer is oxidized during the subsequent deposition of the MgO layer. As a result, a strong interfacial perpendicular anisotropy energy density can be achieved without any post-fabrication annealing treatment. Depending on the HM, further enhancements of the PMA can be realized by thermal annealing to at least 400° C. The ultra-thin HfO₂ layers offer a range of options for enhancing the magnetic properties of magnetic heterostructures for spintronics applications.

Introducing an ultra-thin Hf oxide layer to the surface of FeCoB of as little as 0.1 nm of Hf dusting layer, which is oxidized to HfO₂ during the subsequent MgO deposition process, can yield strong PMA without any post-fabrication annealing treatment. Depending on the HM underlying the FeCoB or alternative FM layer, the system can also, if that is desired, be annealed to at least 400° C. to further enhance the PMA. The Hf dusting technique based on the disclosed technology not only improves the performance of FeCoB/MgO structures but also allows for the PMA devices to be made from a low-damping, low-magnetostriction alloy permalloy (Ni₈₀Fe₂₀) and other Fe alloys. The technique therefore substantially expands the options for engineering magnetic thin film heterostructures for spintronics.

In implementing the disclosed technology, a thin film multilayer structure may be provided to include, adjacent to a PMA magnetic layer, a non-magnetic dusting layer comprising a metal oxide to enable strong perpendicular magnetic anisotropy (PMA). For example, such a thin-film stack may include a ferromagnetic metal layer and a non-magnetic dusting layer. The ferromagnetic metal layer may include any ferromagnetic material that includes Fe as a component, including FeCoB, FeCo, FeB, etc., as well as tertiary alloys and compounds for which Fe is a component. In some implementations of the disclosed technology, the non-magnetic dusting layer may include a metal oxide such as hafnium oxide (HfO₂), yttrium oxide (Y₂O₃), zirconium dioxide (ZrO₂), other transition metal oxides such as TiO₂, other rare earth oxides, or a stable metal oxide with high energy of formation similar to or better than HfO₂. In some implementations, the above thin film multilayer structure may further include, on the dusting layer, a capping layer (not shown in FIG. 5) such as MgO to exhibit both strong PMA and strong tunneling magnetoresistance effect.

The thin non-magnetic metal oxide dusting layer can be made by oxidizing metal dusting layer into metal oxide during the subsequent deposition of MgO via a standard sputtering step. The high PMA can be achieved without any high temperature post-fabrication annealing treatment. The annealing treatment can further enhance the PMA.

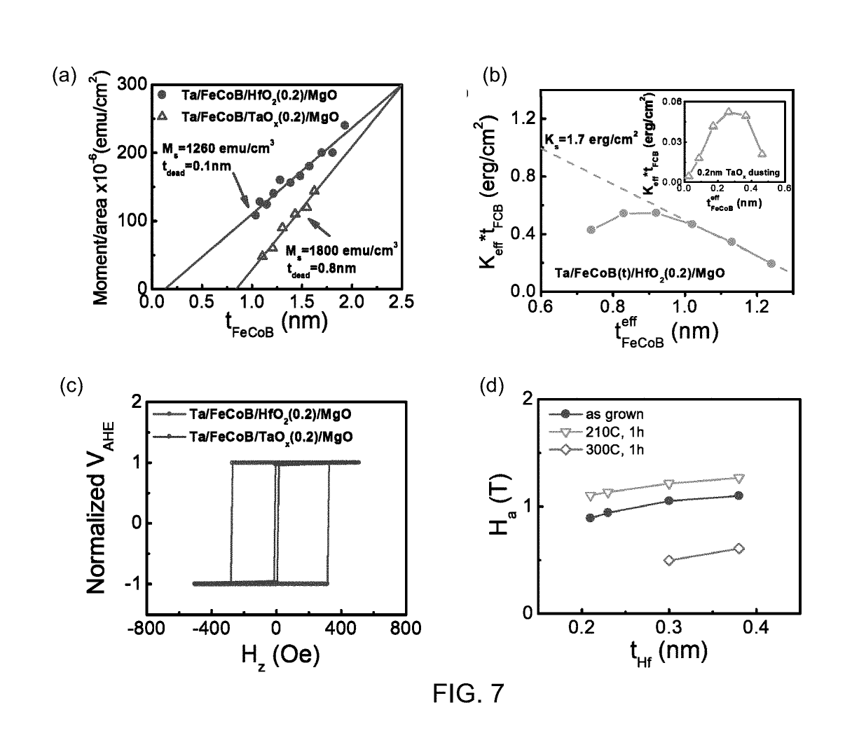

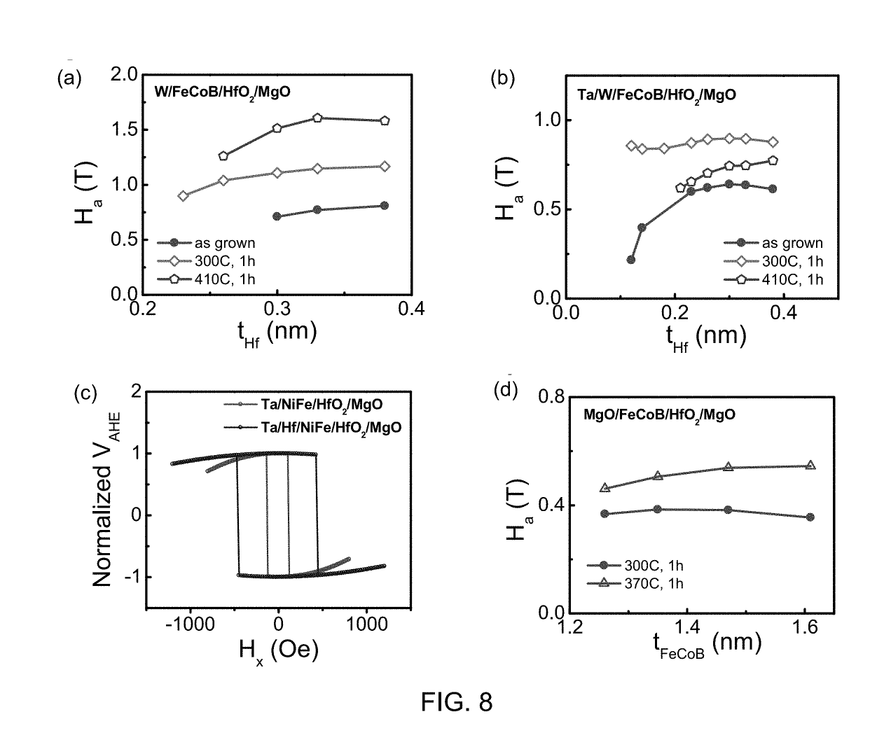

The enhanced PMA field from having a non-magnetic dusting layer comprising a metal oxide formed next to the PMA magnetic layer can be quite large based on tested samples. For example, the enhanced PMA field may be about the 10,000 Oe, as in FIGS. 7(d) and 8(a) showing PMA field as a function of Ta and W of samples and the anisotropy fields can reach (and even be larger than) 1 Tesla (see y axis), which is 10,000 Oe after the unit transformation (i.e., 1 T=10,000 Oe). The PMA strength of the thin film multilayer structure is at least about 5,000 Oersted (0.5 T), at least about 6,000 Oersted (0.6 T), at least about 7,000 Oersted (0.7 T), at least about 8,000 Oersted (0.8 T), at least about 9,000 Oersted (0.9 T), at least about 10,000 Oersted (1 T), at least about 11,000 Oersted (1.1 T) or at least about 12,000 Oersted (1.2 T), as grown without any post-fabrication annealing treatment. The PMA strength of the thin film multilayer structure is at least about 5,000 Oersted (0.5 T), at least about 6,000 Oersted (0.6 T), at least about 7,000 Oersted (0.7 T), at least about 8,000 Oersted (0.8 T), at least about 9,000 Oersted (0.9 T), at least about 1.0 Oersted (1.0 T), at least about 11,000 Oersted (1.1 T), at least about 12,000 Oersted (1.2 T), at least about 13,000 Oersted (1.3 T), at least about 14,000 Oersted (1.4 T), at least about 15,000 Oersted (1.5 T), or at least about 16,000 Oersted (1.6 T) with annealing treatment.

The thin film multilayer structure can be used as an element of various devices, including a magnetic device, a magnetic cell, a random access memory, a spin-transfer-torque magnetic memory, a magnetic memory elements based on (chiral or not) domain wall structures or on magnetic skyrmions, for such as racetrack magnetic memory and logic devices, or magnetic based oscillators.

The perpendicular magnetic anisotropy occurring between transition metal ferromagnetic material and MgO may be understood as being caused by the spin-split hybridization of the orbital bonds between Fe and O, or in particular from the Fe—O—Mg bonds. This hybridization may be used to interpret the enhanced PMA in the disclosed technology based on Hf dusting layers for the case of Fe—O—Hf bonding. This enhanced PMA may be due to the role of the Hf, and/or due to the fact that there is a higher density of O in the HfO₂ material than in the MgO case, and hence more O—Fe bonds are possible at the interface.

In some implementations of the disclosed technology, MgO or other oxides may be disposed on top of the oxidized Hf to get the PMA effect to exhibit a strong tunneling magnetoresistance effect. In other implementations of the disclosed technology, the Hf dust layer can be deposited on top of the ferromagnetic layer and is then oxidized without oxidizing the underlying material.

Achieving robust perpendicular magnetic anisotropy (PMA) in heavy metal (HM)/ferromagnet (FM)/oxide thin-film heterostructures can be beneficial for the implementation of ultra-high density memory elements based on the spin transfer torque (STT) switching of perpendicularly magnetized tunnel junctions (MTJs). Strong PMA is also desirable for constructing the perpendicularly magnetized nanowire structures needed to enable manipulation of domain walls with chiral symmetry and novel magnetic chiral structures such as skyrmions by the spin Hall effect. In some implementation of the disclosed technology, FeₓCo_{y}B_{z} (FeCoB)/MgO may be used as the FM/oxide combination that yields the strong PMA and low damping desirable for practical devices. The PMA originates from the strong spin-orbit interaction in the hybridized 3d Fe-2p O bonding at the FeCoB/MgO interface. Even there obtaining significant PMA requires an annealing step that can compromise the layers in the magnetic heterostructure. The addition to the surface of FeCoB of an average coverage of as little as 0.1 nm of Hf “dusting,” which is oxidized to HfO₂ during the subsequent MgO deposition process, can yield strong PMA without any post-fabrication annealing treatment. Depending on the HM underlying the FeCoB or other FM layer, the system can also, if that is desired, be annealed to at least 400° C. to further enhance the PMA. The dusting layer such as a Hf dusting layer not only improves the performance of FeCoB/MgO structures but also allows for the first time PMA devices to be made from the low-damping, low-magnetostriction alloy permalloy (Ni₈₀Fe₂₀) and other Fe alloys. The technique therefore substantially expands the options for engineering magnetic thin film heterostructures for spintronics.

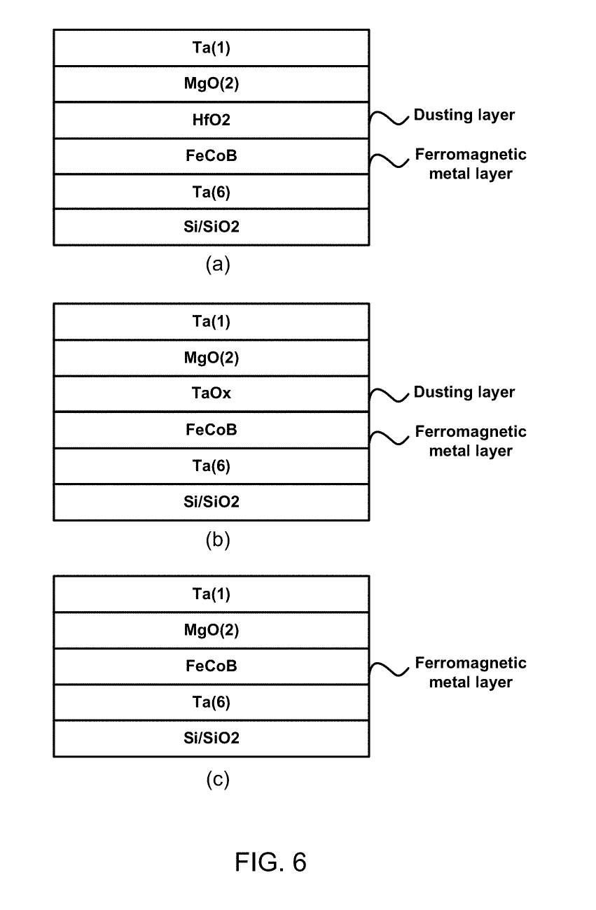

FIG. 6 shows examples of thin-film magnetic structures in accordance with some implementations of the disclosed technology. In FIG. 6(a), an example of the thin-film magnetic structure with HfO₂ dusting layer may include Si/SiO₂/Ta(6)/FeCoB(t_{feCoB})/HfO₂(t_{Hf}))/MgO(2)/Ta(1). In FIG. 6(b), another example of the thin-film magnetic structure with TaOₓ dusting layer may include Si/SiO₂/Ta(6)/FeCoB(t_{feCoB})/TaOₓ(tₜₐ)/MgO(2)/Ta(1). In FIG. 6(c), another example of the thin-film magnetic structure may include Si/SiO₂/Ta(6)/FeCoB(t_{feCoB})/MgO(2)/Ta(1) without any dusting layer. Here, the numbers in parentheses are the thicknesses in nm. Since the complete oxidation of the insulator at the Fe alloy/oxide interface is held to be critical for the formation of PMA in HM/Fe alloy/oxide heterostructures, x-ray photoelectron spectroscopy (XPS) measurements can be performed on an as-grown Ta(6)/FeCoB(1.2)/HfO₂(0.2)/MgO/Ta. Ion etching may be used to remove most of the Ta capping layer before performing XPS.

FIGS. 7(a)-7(d) show magnetic properties of the Ta-based samples with HfO₂ or TaOₓ passivation layers, including (a) VSM measurements of magnetization, (b) effective anisotropy energy density K_{eff} determined from anomalous Hall measurements as a function of in-plane magnetic field, and (c) anomalous Hall measurements as a function of out-of-plane magnetic field, for the as-grown samples Ta(6)/FeCoB(t_{feCoB})/HfO₂(0.2)/MgO/Ta and Ta(6)/FeCoB(t_{feCoB})/TaOₓ(0.2)/MgO/Ta (the solid and dashed straight lines are linear fits to the data), and (d) the perpendicular anisotropy fields of Ta(6)/FeCoB(0.8)/HfO₂(t_{Hf})/MgO/Ta samples as deposited and after different post-fabrication annealing treatments.

FIG. 7(a) shows the magnetic moment per area as a function of t_{feCoB} for thin-film magnetic structures with the Hf dusting layer and also for thin-film magnetic structures with the Ta dusting layer, as measured by vibrating sample magnetometry (VSM). Here, the average thickness is that of the deposited metal, before oxidation. The thin-film magnetic structures with the Hf dusting layer show a saturation magnetization of Mₛ=1260 emu/cm³ and a very small apparent “dead layer” at a thickness t_{d} of about 0.1 nm. In contrast, the samples with the Ta dusting layer indicate a thickness t_{d} of about 0.8 nm and a much larger Mₛ=1800 emu/cm³. These results are comparable to some previous studies of annealed (˜300 C) Ta/FeCoB/MgO samples where the dead layer has been attributed to undesirable diffusion of Ta into the FeCoB, perhaps to the ferromagnet/oxide interface. Thus, the thick dead layer in the thin-film magnetic structures with the Ta dusting layer may be attributed to the intermixing of Ta and FeCoB during the deposition of the Ta dusting layer.

While Ta/FeCoB/MgO structures with a thin FM layer typically only exhibit, at most, a weak perpendicular magnetic anisotropy (PMA) in the as-deposited state, a robust PMA behavior may be observed in as-deposited structures with the HfO₂ dusting layer. For example, as shown in FIG. 7(b), the PMA energy density K_{eff} ≡HₐMₛ/2 may be plotted as a function of the effective thickness of the FeCoB t_{FeCoB}^{eff}=t_{FeCoB}−t_{d} for the samples with Hf dusting layer, e.g., Ta/FeCoB(t_{FeCoB})/HfO₂(0.2)/MgO samples. Here, Hₐ is the perpendicular magnetic anisotropy field as determined from measurement of the anomalous Hall voltage response to an in-plane magnetic field, and the values of Mₛ determined from the VSM measurements discussed above may be used. When t_{FeCoB}^{eff} is sufficiently K_{eff}·t_{FeCoB}^{eff}=(Kᵥ−2πM_{z}²)·t_{FeCoB}^{eff}+K_{z} where Kᵥ(Kₛ) is the bulk (interfacial) magnetic anisotropy energy density, a linear fit may be used to this plot to determine that the surface magnetic anisotropy density Kₛ=1.74±0.09 erg/cm². For Ta and Hf base layer systems without the Hf dusting layer, comparable anisotropies can be obtained only via high temperature (≥200° C.) annealing. FIG. 7(b) shows the effective PMA energy density K_{eff} for the samples with a 0.2 nm Ta dusting layer. Here, K_{eff} for the Ta dusting layer is an order smaller than for the Hf dusting layer. This indicates that Ta dusting is much less effective than Hf dusting, or Zr, or some other more appropriate dusting, in enhancing the interfacial perpendicular magnetic anisotropy energy density. This is most likely due to the detrimental interaction of Ta with the ferromagnetic surface that also creates the magnetic dead layer.

Consistent with the strong Hₐ of the HfO₂ passivated samples, the coercive field He of those PMA structures is relatively high, typically equal to or higher than 300 Oe, in comparison to quite low values below 20 Oe for the Ta dusting samples, which as noted above is not nearly as effective in enhancing the interfacial perpendicular magnetic energy density Kₛ as is Hf dusting. Examples of the field switching that is obtained with an external field applied normal to the film surface are provided in FIG. 7(c) for a Ta(6)/FeCoB(1.1)/HfO₂(0.2)/MgO/Ta(1) sample and a Ta(6)/FeCoB(1.1)/TaOₓ(0.2)/MgO/Ta(1) sample. Since He of such PMA samples depends on both the anisotropy field and its uniformity, which together act to set the field for magnetic reversal, further enhancement in He should be expected with refinements in the smoothness and uniformity of such heterostructures.

The perpendicular anisotropy fields Hₐ may be measured as a function of HfO₂ thicknesses in a different set of thin-film magnetic structures including Ta(6)/FeCoB(0.8)/HfO₂ (t_{Hf})/MgO/Ta with t_{Hf} at about 0.2 to 0.4 nm, as indicated in FIG. 7(d). For the as-grown samples, Hₐ increases with HfO₂ thickness and grows above 1 T when t_{Hf} is equal to or larger than 0.3 nm. This may be due to a more completely continuous HfO₂ layer being formed at the FeCoB/MgO interface as t_{Hf} is increased over this range and hence a higher Fe—O—Hf hybridized bond density that enhances the interfacial PMA.

Previously, high temperature post-fabrication annealing treatment has been considered to be necessary to the achievement of robust PMA in HM/FeCoB/MgO heterostructures. There are generally two important functions of this annealing process, including (i) removal of the over-oxidation of the FeCoB surface that occurs during MgO deposition and (ii) promotion of the out-diffusion of the boron from the initially amorphous FeCoB to obtain a more ordered, crystalline FeCo/MgO interface. The test results disclosed in this document indicate that the first function is the more important, or alternatively that the Fe—O—Hf hybridized bonds results in a stronger spin-splitting of the orbitals than does the Fe—O—Mg bonds.

Obtaining strong PMA in HM/Fe alloy/Oxide systems without the necessity of thermal annealing may facilitate important applications as this could avoid complications such as material diffusion/intermixing during high temperature excursions. On the other hand, since many applications of PMA heterostructures do require high temperature processing, both for integration with Si circuits and to attain a high tunneling magnetoresistance (TMR) with MTJs, this patent document discloses how different heat treatments affect the PMA of our HfO₂ structures. FIG. 7(d) shows that after annealing at 210° C. for 1 hour, Hₐ increases for every HfO₂ thickness studied, while the general dependence of Hₐ on t_{Hf} remains. However, after annealing at 300° C. for 1 hour the PMA deteriorates, with a much weaker PMA retained only for t_{Hf} equal to or larger than 0.3 nm. This deterioration may be due to the diffusion of Ta from the base layer since such diffusion has been known to damage the interfacial PMA in the Ta based PMA systems.

FIGS. 8(a)-8(d) show PMA characterization for HfO₂ passivation samples with different underlayers and ferromagnetic layers, including (a) the perpendicular anisotropy fields of (a) beta-W(4)/FeCoB(0.8)/HfO₂(t_{Hf})/MgO/Ta and (b) the perpendicular anisotropy fields of Ta/alpha-W(4)/FeCoB(0.8)/HfO₂(t_{Hf})/MgO/Ta after different post-fabrication annealing treatments, and (c) anomalous Hall measurements of the as-grown samples Ta(6)/NiFe(1.4)/HfO₂(0.2)/MgO/Ta and Ta(6)/Hf(0.5)/NiFe(1.5)/HfO₂(0.2)/MgO/Ta as a function of in-plane magnetic field, and (d) the perpendicular anisotropy fields of MgO(1.6)/FeCoB(t_{FeCoB})/HfO₂(0.3)/MgO(0.8)/Ta samples after different post-fabrication annealing treatments. The Ta in-diffusion problem discussed above can be avoided by the use of other heavy metal base layers, especially those with strong spin Hall effects, e.g. W and Pt. FIG. 8(a) shows the values of Hₐ obtained from a set of W(4)/FeCoB(0.8)/HfO₂(t_{Hf})/MgO(1.6)/Ta samples as a function of t_{Hf} for the as-deposited case, after 1 hour at 300° C., and after 1 hour at 410° C. Here the W is in the high resistivity beta-W phase. The anisotropy increases with annealing temperature, and with 410° C. vacuum annealing, Hₐ above 1.6 T may be obtained for a sufficiently thick HfO₂ passivation layer, indicative of an interfacial anisotropy energy density equal to or lower than 1.5 ergs/cm². When a 1 nm Ta seeding layer is used before the deposition of the W layer, it results in the W being smoother and also in the lower resistivity alpha-phase. As shown in FIG. 8(b), relatively high anisotropy fields are obtained after 300° C. annealing of such Ta(1)/W(4)/FeCoB(0.8)/HfO₂(t_{Hf})/MgO(1.6)/Ta samples for t_{Hf}≥0.1 nm, but annealing at 410° C. degrades Hₐ, particularly for the heterostructures with thinner HfO₂, likely due to in-diffusion of Ta from the bottom seeding layer.

While some implementations of the disclosed PMA heterostructure utilize either Ta/FeCoB/MgO or Pt/Co/Oxide multilayers, where in the latter case the PMA originates largely from spin orbit effects at the Pt/Co interface, other magnetic layers with attractive properties, such as Ni₈₀Fe₂₀, may be used. Some embodiments of the disclosed technology can obtain significant interfacial anisotropy by using a suitable combination of HfO₂ and Ni₈₀Fe₂₀, e.g. with Ta/Ni₈₀Fe₂₀/HfO₂/MgO and with Ta/Hf(0.5)/Ni₈₀Fe₂₀/HfO₂/MgO multilayers. In some embodiments of the disclosed technology, an amorphous Hf(0.3-1 nm) spacer may be used between the Ta base layer and the NiFe, which presumably helps to accommodate the crystalline mismatch between the Ta and the NiFe. FIG. 8(c) shows anomalous Hall measurements as a function of an in-plane magnetic field for as-deposited Ta based NiFe(1.5)/HfO₂(0.2)/MgO samples with and without the Hf spacer at the Ta/NiFe interface. Hₐ for the structure without Hf spacer is 1.1 kOe, while for the sample with the 0.5 nm Hf spacer, Hₐ is doubled to 2.1 kOe, indicative of an interfacial anisotropy energy density Kₛ of about 0.8 erg/cm². Similar values of Kₛ with Pt/Hf(0.5)/FeCoB/HfO₂(0.2)/MgO multilayers may be obtained both as deposited and after 300° C. annealing. Thus, the combination of a HfO₂ passivation layer at the Fe alloy/oxide interface together with a thin Hf spacer layer between the HM and the Fe alloy (when needed due to crystalline mismatch between the HM and the Fe alloy) can be a robust strategy for engineering the PMA of a range of thin-film magnetic heterostructures.

An MTJ technology for spin transfer torque applications may include a second, thinner MgO layer on the other side of the FeCoB free layer, opposite to the MgO tunnel barrier interface. This enhances K_{eff} of the free layer permitting the use of a thicker layer with more thermal stability, and also suppresses the magnetic damping enhancement that would otherwise occur via spin pumping to the adjacent normal metal contact. In some embodiments of the disclosed technology, this approach may be modified by depositing multilayer stacks of MgO(1.6)/FeCoB(t_{FeCoB})/HfO₂(0.2)/MgO(0.8)/Ta onto oxidized Si substrates. FIG. 8(d) shows a plot of Hₐ of such samples as a function of t_{FeCoB}. Quite strong anisotropy fields are obtained to high values of t_{FeCoB}, particularly for the samples annealed at 370° C. Field modulated ferromagnetic resonant studies of such a heterostructure with t_{FeCoB} at 1.6 nm show that a magnetic damping parameter α is at 0.009, while in a Ta/FeCoB(1.6)/MgO(1.6)/Ta sample the magnetic damping parameter α is at 0.02.

An important question in terms of application is whether MTJ's with a HfO₂ passivation layer at the magnetic free layer/tunnel barrier interface can provide sufficiently high TMR to be useful for STT and other spintronics applications. As reported previously, a TMR of 80% has been achieved with an in-plane magnetized Pt/Hf/FeCoB (1.6)/MgO(1.6)/FeCoB/Ru/Ta MTJ structure annealed at 300° C., where analytical STEM reveals substantial HfO₂ (˜0.1 nm of Hf content) at or within the tunnel barrier while the greatly reduced demagnetization field, about 4 kOe, indicates a substantial Kₛ due to the HfO₂ dusting layer at the FeCoB/MgO interface.

In various embodiments of the disclosed technology, the perpendicular magnetic anisotropy in HM/Fe alloy/MgO heterostructures can be dramatically strengthened by incorporating a very thin HfO₂ dusting layer at the Fe alloy/MgO interface. In HM/FeCoB/MgO devices, the dusting layer enables strong PMA even in the absence of the post-deposition annealing step that has previously been necessary. When annealing is desired, the dusting layer allows the PMA to remain strong for annealing temperatures even above 400° C., provided a proper base layer is utilized, a much higher limit than for some current STT-MRAM prototype technologies. This can allow easier integration with Si circuitry. The HfO₂ dusting layer can also create robust PMA using magnetic materials for which previously this has been impossible, thereby expanding the portfolio of magnetic materials available for PMA technologies beyond just FeCoB. In some embodiments of the disclosed technology, PMA with thin-film Ni₈₀Fe₂₀ may be utilized due to its low damping and low magnetostriction. Overall, the strengthening of PMA using HfO₂ dusting layers has great promise both for enhancing the performance of spin-transfer-torque magnetic memory based on PMA magnetic tunnel junctions and also for improving control of chiral domain walls and skyrmion structures within PMA HM/Fe alloy/MgO structures.

In some embodiments of the disclosed technology, a thin-film magnetic structure may be formed via standard direct current (DC) sputtering (with RF magnetron sputtering for the MgO layer), with a base pressure below 4×10⁻⁸ Torr. The DC sputtering condition may be 2 mTorr Ar pressure and 30 watts power. To form the interfacial HfO₂ an ultrathin Hf dusting layer may be first sputtered on the FeCoB with a low deposition rate of 0.01 nm/s, and the MgO layer may then be sputtered on the Hf layer with a growth rate of 0.005 nm/s (at 100 watts power, 2 mTorr Ar) to oxidize the Hf. In each case the top Ta film serves as a capping layer to protect the underlayers from degradation during atmospheric exposure.

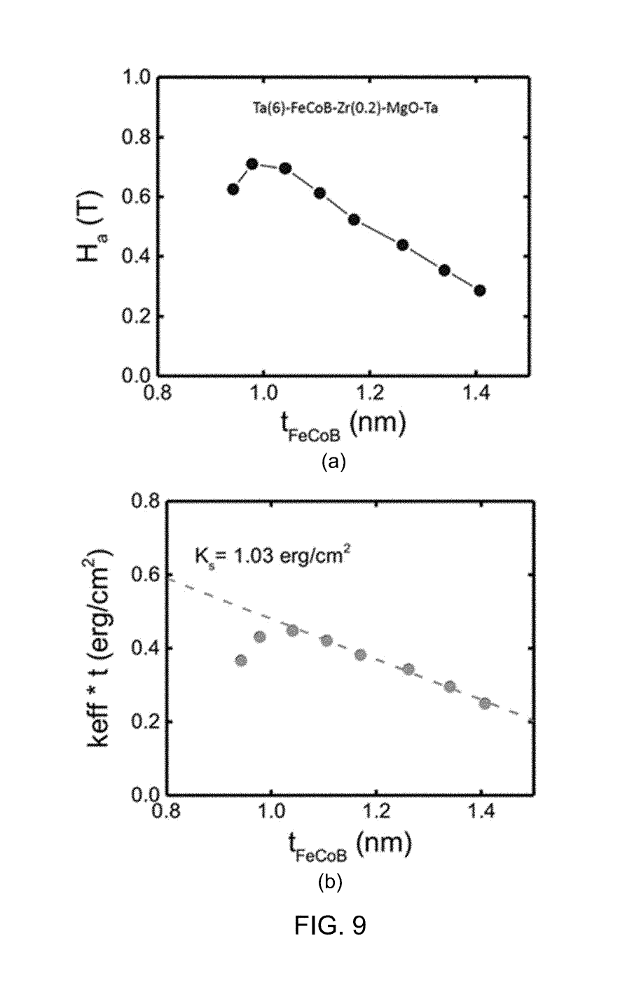

FIG. 9(a) shows the result of the use of a ZrO₂ dusting layer on the as-grown perpendicular magnetic anisotropy field Hₐ (in units of Tesla) as a function of the thickness of the FeCoB layer that is dusted with 0.2 nm of Zr. The Zr is then oxidized to form the ZrO₂ dusting layer during the deposition of the MgO capping layer. The FeCoB is deposited on a 6 nm thick Ta base layer. FIG. 9(b) shows the effective perpendicular magnetic anisotropy energy density as a function of the FeCoB thickness for the same samples as in (a). The interfacial perpendicular anisotropy energy density for this as-grown sample with ZrO₂ dusting layer is Kₛ=1.03 erg/cm². In an embodiment of the disclosed technology, the magnetic structure with enhanced PMA may use Zr for the dusting layer since ZrO₂ is also a stable metal oxide and has a similar standard enthalpy of formation as HfO₂. ZrO₂ dusting layers show similar results to that obtained from the use of HfO₂ dusting layers as shown in Table 1, particularly after high temperature annealing which can be beneficial for integration of ST-MRAM with Si electronic circuits. In FIG. 9 is shown (a) examples of the perpendicular magnetic anisotropy field Hₐ that can be obtained with the use of 0.2 nm of Zr that is then converted to ZrO₂ dusting. This dusting is produced on the top of a FeCoB layer of thickness ranging from 0.9 to 1.4 nm. In FIG. 9(b) is shown the effective magnetic anisotropy energy density as a function of the FeCoB thickness and also the interfacial magnetic anisotropy energy density Kₛ that is responsible for this thickness dependence.

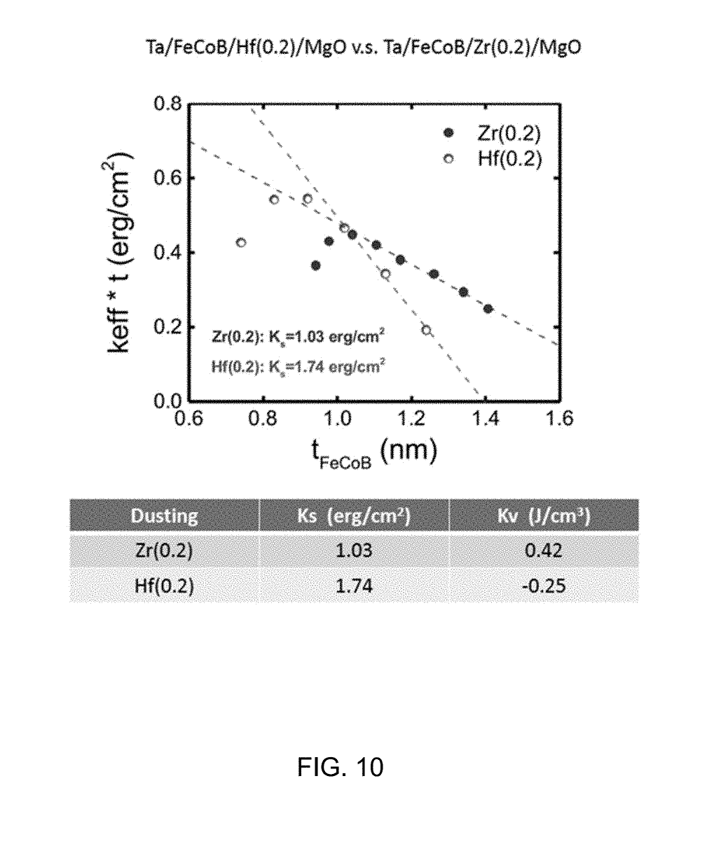

FIG. 10 provides a comparison of the as-grown magnetic anisotropy behavior obtained with HfO₂ dusting and obtained with ZrO₂ dusting. In both cases the metal dusting layer before conversion to metal oxide was 0.2 nm. The table in the figure provides a comparison of both the interfacial magnetic anisotropy energy density Kₛ and the volume magnetic anisotropy energy density Kᵥ. This illustrates the differences in behavior that can be obtained to best meet the needs of particular implementation with different dusting layers. In FIG. 10 is shown a comparison between the magnetic anisotropy energy density as obtained from an implementation of HfO₂ dusting and from ZrO₂ dusting. Both dusting layers are effective in obtaining high values of Kₛ in the as-grown state, but differ in the quantitative values of both Kₛ and in the volume anisotropy Kᵥ. Such differences may be utilized to match the needs of particular implementation of the disclosed technology.

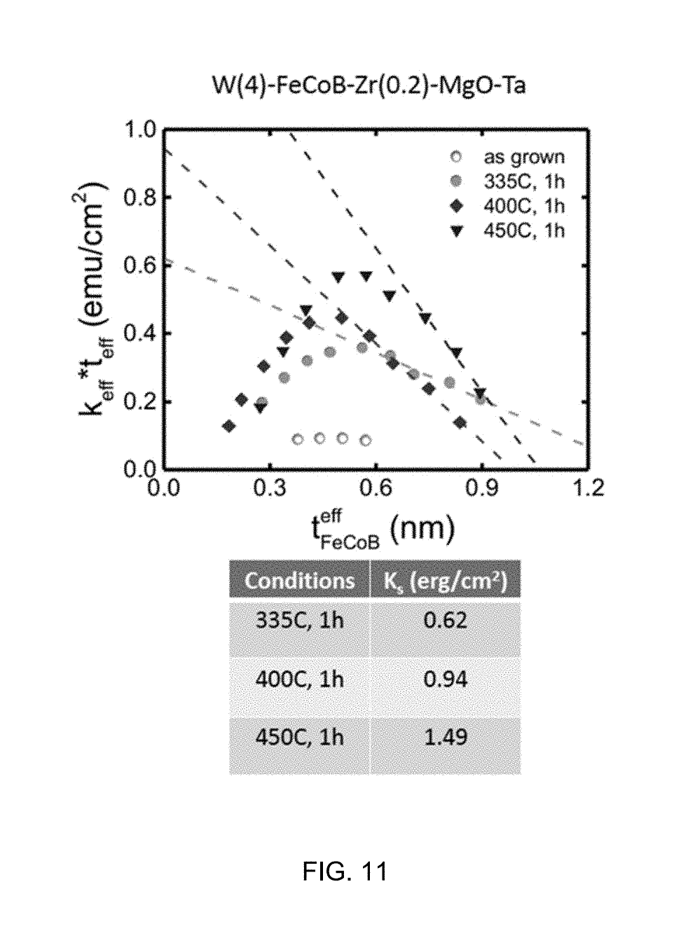

FIG. 11 shows the variation of the effective magnetic anisotropy energy density, K_{eff} as a function of the effective thickness of the FeCoB; that is after subtraction of the small thickness of a magnetic dead layer. The results show that in this case of the use of W as a base layer the ZrO₂ dusting is effective for maintaining perpendicular magnetic anisotropy up to 450° C., an exceptionally high temperature for magnetic thin film structures. In FIG. 11 is shown the variation of the effective anisotropy energy density K_{eff} as obtained with W/FeCoB/ZrO₂(0.2)/MgO magnetic structures as a function of the magnetic thickness of the FeCoB (t^{eff}) for different annealing temperatures. The ability to maintain a significant K_{eff} after annealing to 450° C. demonstrates the utility of the disclosed technology for integration of magnetic structures onto Si wafers that require high temperature processing.

In another embodiment of the disclosed technology, the magnetic structure with enhanced PMA may utilize Y for the dusting layer since Y₂O₃ has an even higher standard enthalpy of formation than HfO₂. As in the case of Hf oxide and Zi oxide dusting layer, the Y dusting layer may be used to protect the ferromagnetic layer from oxidation during the deposition of the MgO and also provide a stronger spin-orbit splitting of the electronic states at the Fe—O—Y bonds, which would enhance the perpendicular magnetic anisotropy.

In another embodiment of the disclosed technology, the magnetic structure may include, as the dusting layer, any other metallic element that has a particularly high standard enthalpy of formation for a stable oxide, and that does not have a detrimental interaction with the magnetic material that results in a significant magnetic “dead layer”. Suitable metallic elements include Ti and other metals that form stable XO2 oxides, the same stoichiometry as HfO2. Yttrium, scandium, lutetium, all of which form stable X2O3 oxides where X is the metal component, may also be used to implement the disclosed technology. In another embodiment of the disclosed technology, the magnetic structure may include, as the dusting layer, binary oxides of metals (X) that have a higher standard enthalpy of formation of the oxide than MgO with stoichiometry XyOz where y≤z, in which there is at least one oxygen ion in the oxide for every metal ion, preferably more.

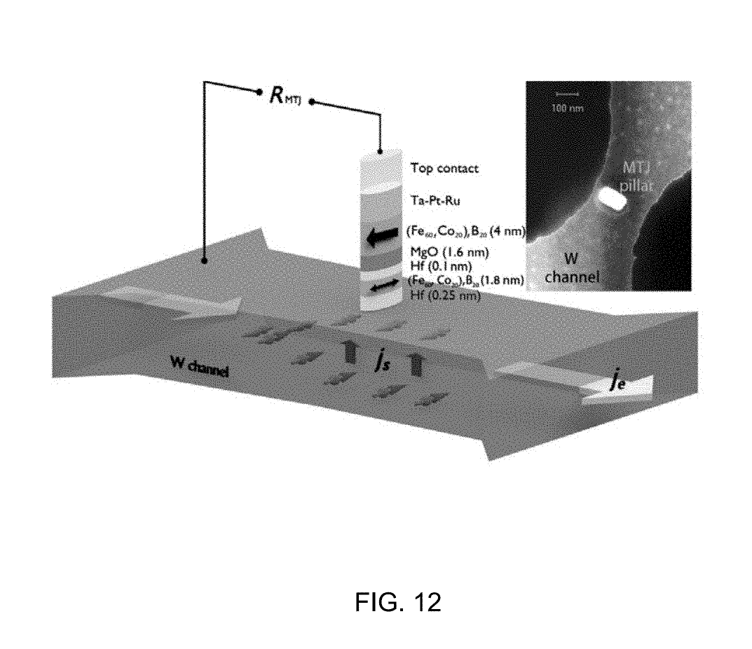

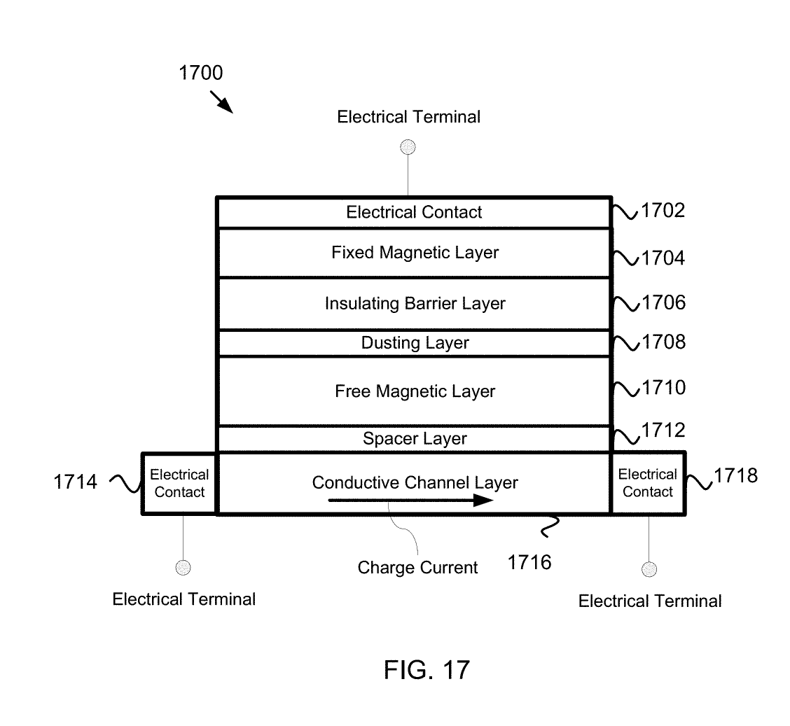

Magnetic devices can be constructed by coupling a spin Hall effect (SHE) metal layer to a free magnetic layer exhibiting a magnetization direction that can be changed for various configurations. For example, a MTJ junction can be formed over a SHE metal layer where the layers in the MTJ and the SHE metal layer, e.g., selection of the materials and dimensions, are configured to provide a desired interfacial electronic coupling between the free magnetic layer and the SHE metal layer to generate a large flow of spin-polarized electrons or charged particles in the SHE metal layer under a given charge current injected into the SHE metal layer and to provide efficient injection of the generated spin-polarized electrons or charged particles into the free magnetic layer of the MTJ. Such an SHE metal layer serves as an electrically conductive channel layer. Each of the free magnetic layer or the pinned magnetic layer can be a single layer of a suitable magnetic material or a composite layer with two or more layers of different materials. The free magnetic layer and the pinned magnetic layer can be electrically conducting while the barrier layer between them is electrically insulating and sufficiently thin to allow for electrons to pass through via tunneling. The spin Hall effect metal layer can be adjacent to the free magnetic layer or in direct contact with the free magnetic layer to allow the spin-polarized current generated via a spin Hall effect under the charge current to enter the free magnetic layer. Various 3-terminal magnetic devices may be constructed by coupling a SHE metal layer to MTJ junctions as illustrated in FIGS. 12 and 17 in this document. U.S. Pat. No. 9,691,458 entitled “Circuits and devices based on spin hall effect to apply a spin transfer torque with a component perpendicular to the plane of magnetic layers,” U.S. Pat. Nos. 9,502,087 and 9,230,626 entitled “Electrically gated three-terminal circuits and devices based on spin hall torque effects in magnetic nanostructures apparatus, methods and application” and U.S. Pat. No. 9,105,832 entitled “Spin hall effect magnetic apparatus, method and applications” provide additional examples and technical features of some SHE-MTJ devices and are incorporated by reference as part of the disclosure of this patent document.

FIG. 12 shows a Hf-spacer-Hf-dusting structure and measurement schematics along with a SEM image showing an example elliptical nano-pillar MTJ on top of a W SHE channel after it has been defined by electron-beam lithography and argon ion milling. Spin-orbit torque (SOT) from the spin Hall effect (SHE) in heavy metals (HMs) can rapidly and reliably switch an adjacent ferromagnet (FM) free layer of a nanoscale magnetic tunnel junction in a three-terminal configuration (3T MTJ). This effect provides the strategy for a fast current- and energy-efficient cache magnetic memory. The separate read and write channels in the 3T MTJ geometry offer additional advantages, including faster readout without read disturbance and lower write energy. While the development of SOT switching has focused primarily on nanoscale perpendicularly magnetized (PM) MTJs, their SOT effective-field switching requires much higher currents than can be provided by a reasonably scaled CMOS transistor (current densities in the SH channel are equal to or larger than 1.4×10⁸ A/cm²), and fast low-write-error-rate (WER) switching has not yet been demonstrated. SOT switching of a PM MTJ also requires an in-plane bias field to obtain deterministic reversal, and some implementations of the disclosed technology may utilize an antiferromagnetic pinning layer or an electric field to provide this bias field. In-plane-magnetized (IPM) 3T MTJs implemented based on the disclosed technology may achieve a dramatic performance improvement since, for example, the strong SOT arising from nanochannels of β-phase W is combined with the effects of Hf atomic layer modifications of the FM-MgO and HM/FM interfaces that, respectively, enhance the interfacial perpendicular magnetic anisotropy (PMA) energy density and reduce interfacial spin-memory loss. An antidamping SOT switching current density here may be about 5.4×10⁶ A/cm². Various implementations of the disclosed technology also achieve reliable switching with 2-ns pulses, at about 10⁻⁶ of write error rate (WER), to the beneficial assistance of the field-like SOT arising from the spin current generated by the W spin Hall effect, or from the spin Hall effect in other metals, such as Pt and various Pt alloys.

The high performance 3T-MTJ devices in accordance with an implementation of the disclosed technology may be lithographically patterned from a thin film multilayer stack sputter-deposited onto an oxidized Si wafer. For example, a 3T-MTJ device may include W(4.4)/Hf(0.25)/Fe₆₀Co₂₀B₂₀(1.8)/Hf(0.1)/MgO(1.6)/Fe₆₀Co₂₀B₂₀(4)/Ta(5)/Ru(5) (thickness in nanometers), where W represents the high-resistivity beta-phase of W.

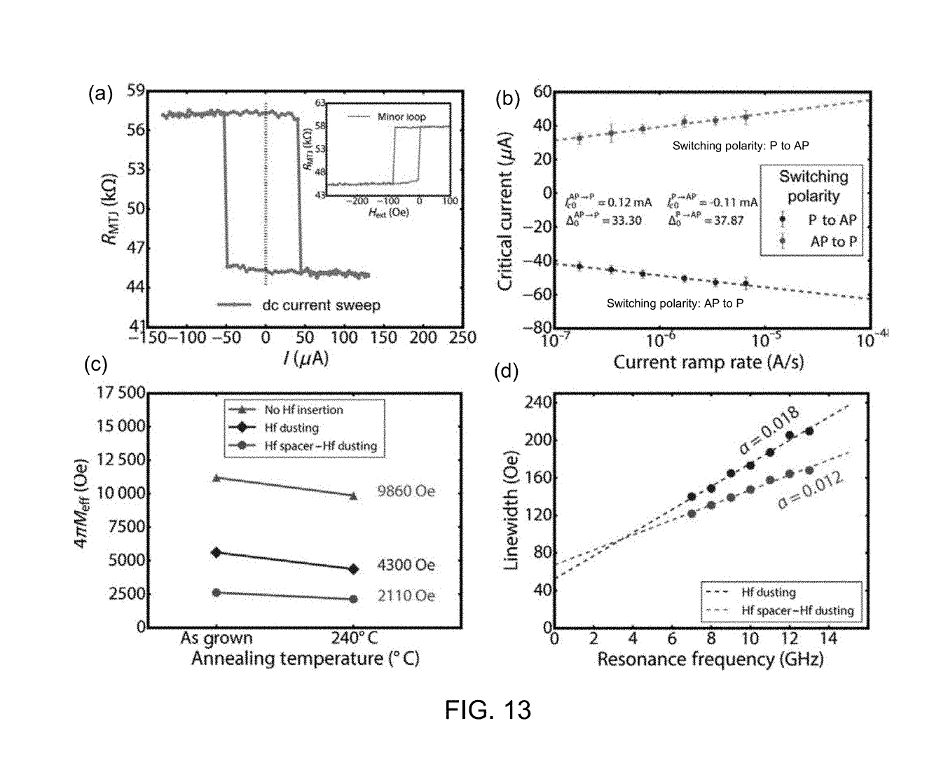

FIG. 13(a) shows current-induced switching loop of the MTJ free layer showing a thermally assisted switching current of 50 μA, where the device is 190×30 nm² and is situated on a 480-nm wide W channel, along with an inset showing an in-plane field-switching minor loop of the free layer. FIG. 13(b) shows current ramp rate measurement on the device of FIG. 13(a). Fitting to the macrospin model gives a zero-thermal-fluctuation critical current of 115 μA with a thermal stability factor of 35.6. FIG. 13(c) shows the free layer effective demagnetization field change with annealing temperature for a Hf-spacer-Hf-dusting structure compared to that of a Hf-dusting-only structure and a structure without Hf insertion as measured by flip-chip ferromagnetic resonance (FMR). M_{eff} significantly decreases in the samples with Hf dusting due to enhanced interfacial perpendicular anisotropy. FIG. 13(d) shows linewidths at different resonance frequencies (applied fields) for the Hf-dusting-only sample and the Hf-spacer-Hf-dusting sample measured by flip-chip FMR. Both samples are annealed at 240° C. The damping decreases significantly with the insertion of the 0.25-nm Hf spacer.

The W-based in-plane-magnetized (IPM) 3T-MTJ devices implemented based on an implementation of the disclosed technology having a high-aspect-ratio, 30 nm×190 nm, and fabricated on a 480 nm wide W channel may be annealed in an air furnace, for example, at 240° C. for 1 hour after patterning to increase the tunneling magnetoresistance (TMR) of the MTJ and also reduce the switching current as discussed below. The inset to FIG. 13(a) shows the minor magnetic loop response of the MTJ resistance as an in-plane magnetic field Hₑₓₜ is applied along the long axis of the MTJ device and ramped over ±300 Oe, which is sufficient to reverse the orientation of the thin bottom free layer (FL) of the MTJ from being parallel (P) to anti-parallel (AP) to the thicker FeCoB reference layer, but not strong enough to reverse the orientation of the reference layer due to its stronger shape anisotropy. The horizontal offset of the minor loop (˜−50 Oe) is due to the dipole field from the reference layer. All subsequent SOT measurements are taken when this offset is canceled by an appropriate Hₑₓₜ.

The main part of FIG. 13(a) shows the characteristic DC SOT hysteretic switching behavior of the IPM 3T-MTJ as the bias current in the W channel is ramped quasi-statically. The switching polarity is consistent with the negative spin Hall sign of β−W in comparison to that of platinum. For nanoscale MTJs thermal fluctuations assist the reversal during slow current ramps. Within the macrospin or rigid monodomain model the critical current I_{c} that is observed is dependent on the current ramp rate:

$${I}_{c} = {I}_{c 0} \{ 1 - \frac{1}{Δ} ln [ \frac{1}{{t}_{0} Δ} ( \frac{\vert {I}_{c 0} \vert}{\vert \dot{I} \vert} ) ] \} \qquad Eq . ( 1 )$$

Here, I_{c0} is the critical current in the absence of thermal fluctuation, İ is current ramp rate, Δ is the thermal stability factor that represents the normalized magnetic energy barrier for reversal between the P and AP states, and τ₀ is the thermal attempt time which was assumed to be 1 ns.

In FIG. 13(b), to characterize the SOT behavior of the in-plane-magnetized (IPM) 3T-MTJ devices implemented based on the disclosed technology, the mean switching current for İ varying from 10⁻⁷ A/s to 10⁻⁵ A/s may be measured. By fitting to Eq. (1), the in-plane-magnetized (IPM) 3T-MTJ devices implemented based on the disclosed technology shows nearly symmetric SOT switching results with an averaged zero-fluctuation switching current of |I_{c0}|=115 μA and Δ=35.6. With the W channel width w_{SH}=480 nm and thickness t_{SH}=4.4 nm this corresponds to a switching current density J_{c0}=5.4×10⁶ A/cm², more than three times lower than reported originally for a W-based 3T-MTJ and by far the lowest yet reported for any 3T-MTJ device with Δ>35.

The different types of SOT devices have different minimum sizes as determined by thermal stability requirements, which in turn will set the current amplitude for switching or domain wall motion. PMA SOT nanodot devices may be implemented with a 40 nm diameter which can corresponds to a minimum current of approximately 300 μA for reversal using a 40 nm wide, 4 nm thick beta-W spin Hall channel. In comparison our in-plane magnetized 3T-MTJ 190 nm×30 nm device would require a switching current of approximately 40 μA for a 190 nm wide channel.

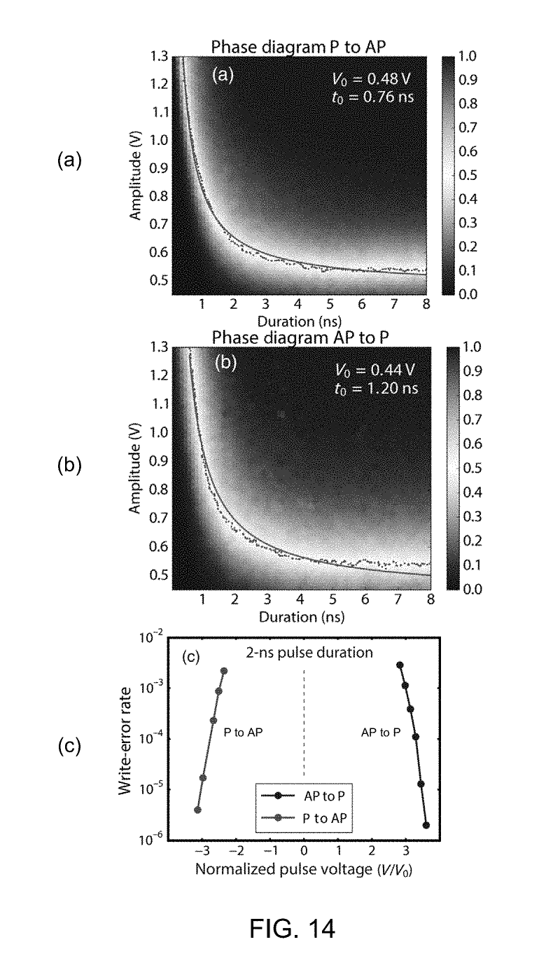

FIGS. 14(a)-14(c) show fast and reliable pulse switching of a Hf-spacer-Hf-dusting sample. FIGS. 14(a) and 14(b) show pulse-switching phase diagrams and macrospin fits for polarities (a) P→AP and (b) AP→P (b), respectively, with the switching probability scale bar on the right. Each point near the curves is a result of 10³ switching attempts. A characteristic switching time of approximately 1 ns and a critical voltage of 0.46 V are obtained after fitting 50% probability points (dots near the curve) to the macrospin model. FIG. 14(c) shows WER measurement results for 2-ns square pulses applied to the device of FIGS. 14(a) and 14(b). Each point is a result of 10⁶ switching attempts. WER of approximately 10⁻⁶ is obtained at sufficiently high-voltage (current) amplitudes for both polarities.

FIGS. 14(a) and 14(b) show separately measured switching phase diagrams for the two cases, P→AP and AP→P, using a fast pulse measurement method, where each data point is the statistical result of 1000 switching attempts, with the scale bar on the right showing the switching probability. Although micromagnetic modeling indicates that for strong short pulses these 3T-MTJ devices do not reverse simply as a rigid domain, the macrospin model may still be utilized as an approximation to characterize the short pulse response by fitting the 50% switching probability boundary between the switching and non-switching regions with:

$$V = {V}_{0} ( 1 + \frac{{τ}_{0}}{t} ) \qquad Eq . ( 2 )$$

The results shown in the solid curves provide a reasonable fit to the data despite the simplifying macrospin assumption. From these fits, the characteristic switching times and critical switching voltages may be 0.76 ns and 0.48V for P→AP and 1.20 ns and 0.44V for AP→P. The short pulse critical switching current (current density) as calculated from and the channel resistance R≈3.6 kΩ is I_{c0}≈120 μA (J_{c0}≈5.9×10⁶ A/cm²), consistent with the ramp rate results.

For cache memory, SOT reversal has to be both fast and highly reliable and in this latter regard our results with this W-based IPM 3T-MTJ approach offer encouraging prospects as indicated by FIG. 14(c), where WER results are shown as measured with 2 ns pulses on the same device. When square switching pulses of increasing voltages are applied to the W channel and recorded states of the device after each switching pulse, for every voltage level, the switching attempts are repeated 10⁶ times and the WER is calculated based on switching probability WER=1−P_{switch}. At 2 ns, WER of close to 10⁻⁶ is achieved for both polarities P→AP and AP→P, which indicates the potential of this approach for high reliability. Note that these results were limited to 10⁻⁶ WER (V≤3.5 V₀) due to the constraint on the highest pulse voltage, that could be applied to the channel that was imposed by a less than optimal electrode design (spreading resistance) and a poor-quality field insulator. Straightforward improvements in both will lower V₀ and enable measurements with V>>V₀.

The observed anti-damping SOT reversal on a≤1 ns timescale is much faster than predicted by the rigid domain, macrospin model. With respect to fast switching with Pt-based IPM 3T-MTJs, the in-W(4)/Hf plane Oersted field H_{Oe} generated by the pulsed current is advantageous in promoting the fast reliable switching because it opposes the anisotropy field H_{c} of the FL at the beginning of the reversal. Due to the opposite sign of the SHE for W-based 3T-MTJs the pulsed H_{Oe} in our case is parallel to He at the beginning of the pulse which micromagnetic modeling indicated should be disadvantageous for very fast reversal. However, W(4)/Hf(0.25)/FeCoB(t_{FeCoB})/Hf(0.1)/MgO/Ta microstrips that have been annealed at 240 C for 1 hour show the anti-damping and the field-like spin-orbit torque efficiencies, ξ_{DL} and ξ_{FL}, of ξ_{DL}=−0.20±0.03 and ξ_{FL}=−0.0364±0.005. This field-like torque efficiency corresponds to an effective field −6.68×10⁻¹¹ Oe/(A/m²) in the MTJ structure with a 1.8 nm free layer that is oriented in opposition to the Oersted field generated by the electric current. Thus, the net transverse field is in opposition to the free layer in-plane anisotropy field at the beginning of the reversal and hence may be playing an important role in the fast, reliable W-based 3T-MTJ results reported here.

In addition to utilizing the high spin torque efficiency of β−W, some implementations of the disclosed technology may employ two other materials enhancements, the sub-monolayer “dusting” and monolayer “spacer” of Hf that were inserted respectively between the FL and the MgO and between the W and the FL, to achieve this exceptionally low pulse current (density) switching performance. For 3T-MTJs the SOT switching current density, within the macrospin model, is predicted to vary as:

$${J}_{c 0} = {I}_{c 0} / {w}_{SH} {t}_{SH} = \frac{2 e}{ℏ} {μ}_{0} {M}_{s} {t}_{FM} α ( {H}_{c} + {M}_{eff} / 2 ) / {ξ}_{DL} \qquad Eq . ( 3 )$$

where e is the electron charge, ℏ is the reduced Plank constant, μ₀ is the permeability of free space, Mₛ is the saturation magnetization of the FL and t_{FM} is the FL's effective magnetic thickness, which were measured to be 1.2×10⁶ A/m and 1.7 nm, M_{eff} ≡Mₛ−Kₛ/t_{FM} is the FL's effective demagnetization field, where Kₛ is the interfacial perpendicular magnetic anisotropy energy density, and a is the effective magnetic damping constant of the FL. To compare the experimental results with the prediction of Eq. (3), a flip-chip ferromagnetic resonance (FMR) measurement of an un-patterned section of the wafer may be conducted to determine M_{eff}=2110 Oe and a=0.012. With these parameter values, from Eq. (3), ξ_{DL}=0.15±0.03 is obtained for the measured device, a bit lower than the result from the ST-FMR measurement of a larger area microstrip of the same heterostructure composition. This difference may be due to an increase in damping resulted from side-wall oxidation of the nanopillar in the lithography process, which can be addressed by in-situ passivation.

The benefits of the Hf insertion layers for reducing the critical current for SOT switching are illustrated by comparisons with FMR measurements performed on two control samples, one with only the Hf dusting, W(4)/FeCoB(1.8)/Hf(0.1)/MgO(1.6)/FeCoB(4)/Ta(5)/Ru(5), and one without either Hf layer W(4)/FeCoB(1.8)/MgO(1.6)/FeCoB(4)/Ta(5)Ru(5). The Hf dusting layer can greatly enhance the perpendicular magnetic anisotropy energy density Kₛ at FM/MgO interfaces. For example, M_{eff} for the Hf dusting layer-only structure may be reduced to 4300 Oe, compared to 9860 Oe for the W MTJ system without any Hf dusting layer as shown in FIG. 13(c). The additional reduction to M_{eff}=2110 Oe for the magnetic structure with the added Hf spacer layer implemented based on the disclosed technology can be attributed to some of that Hf diffusing through the FeCoB to the MgO interface during the anneal to form a HfO₂ dusting layer there. Another benefit of the Hf spacer is that its insertion decreases a very substantially from 0.018 to 0.012, as shown in FIG. 13(d), which shows a passivation of the W surface suppresses reaction between the W and FeCoB that would otherwise result in interfacial spin memory loss. While there is some spin current attenuation from the use of the Hf spacer, its effectiveness in lowering the effective damping, and M_{eff} substantially outweighs that cost.

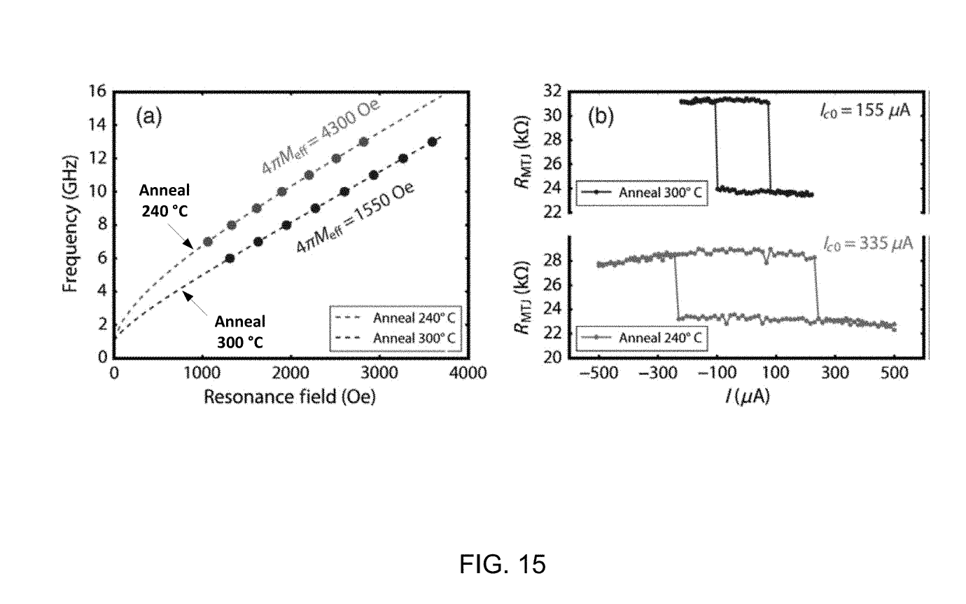

FIGS. 15(a) and 15(b) show the annealing temperature dependence of the Hf-dusting effect, including (a) flip-chip FMR measurement on two Hf-dusting-only samples annealed at 240° C. and 300° C., respectively, showing a further reduction of M_{eff} at higher annealing temperature, and (b) current-induced switching of Hf-dusting-only samples annealed at two different temperatures, 240° C. and 300° C. The spin-torque switching loops indicate a substantial reduction in critical current with the higher-temperature anneal as quantified by the results of ramp rate measurements of I_{c0}.

Integration of MRAM with CMOS usually requires thermal processing above 240° C. Annealing at higher temperatures can also be beneficial in producing higher TMR. The 30 nm×190 nm free layers analyzed above may become thermally unstable due to further decrease in 4πM_{eff} after annealing at 300° C., but it is important to note that the Hf dusting technique itself may become even more effective after processing at a temperature of 300° C. or higher. FIG. 15(a) shows FMR measurements on an un-patterned section of the wafer with only the 0.1 nm Hf dusting layer after it is annealed at 300° C. for one hour, raising the annealing temperature from 240° C. to 300° C. resulted in approximately a 2.5× reduction in 4πM_{eff} from 4300 Oe to 1550 Oe, while there was no material effect on Mₛ and reveals the effectiveness of Hf dusting in enhancing Kₛ. To examine the SOT switching behavior of devices with such low 4πM_{eff}, thermally stable MTJs with larger patterning (e.g., 390 nm×100 nm) formed from the wafer and annealed at the two different temperatures at 240 C and 300 C, respectively, may be used. Consistent with the 4πM_{eff} change, clean SOT switching with a much lower critical current, I_{c0}=155 μA, may be observed after 300 C annealing temperature in comparison to the 240 C critical current I_{c0}=335 μA.

The W-based in-plane magnetized 3T-MTJs implemented based on the disclosed technology achieve nanosecond-scale, reliable, low-amplitude pulse current switching by utilizing a partial atomic layer of Hf dusting between the FL and the MgO which very effectively reduces 4πM_{eff} of the FL, while a further reduction in the required pulse amplitude is achieved by inserting approximately one Hf monolayer between HM and FM which significantly reduces interfacial spin memory loss. This ability to achieve a low 4πM_{eff} with a relatively thick free layer through use of the particularly strong interfacial anisotropy effect of Hf—O—Fe bonds may result in minimizing the detrimental effect of interfacial enhancement of magnetic damping. The thicker free layer may also hinder the formation of localized non-uniformities during the fast reversal that would otherwise result in write errors.

Further decreases in I_{c}, to well below 100 μA, may be achieved with refinements in device design. For example, to ensure successful fabrication, the major axis of the elliptical MTJ nanopillars disclosed above is less than 50% the width of the spin Hall channel so that up to a factor of two reductions in Ic can be expected simply with more aggressive, industry-level lithography. Smaller nanopillars on even narrower channels, e.g., narrower than 100 nm, may be possible through the use of slightly thicker FLs to promote thermal stability, with the robust interfacial magnetic anisotropy effect of the Hf dusting technique providing the means to achieve a low 4πM_{eff} even for t_{FM} of 2 nm or higher. These approaches, in conjunction with an improved device geometry that substantially reduces the spreading resistance, may lower the pulse write current for fast, reliable switching to about 20 μA and the write energy to the scale of 10 fJ or smaller.

The magnetic structure disclosed in this patent document may be implemented in various devices, including two terminal SST-MRAM devices and three-terminal magnetic tunnel junction devices based on a metal layer located under MTJ and structured to exhibit a spin Hall effect. For STT-MRAM technology exhibiting a perpendicular magnetic anisotropy by the ferromagnetic layers, such as for two terminal SST-MRAM devices and circuits, it is desirable to increase the value of the interfacial perpendicular magnetic anisotropy energy density (Kₛ) that can be obtained within the processing constraints. Thus the utilization of the metal-oxide dusting layer should be implemented to maximize the interfacial perpendicular magnetic anisotropy energy density (Kₛ) within the constraints of obtaining a sufficiently high tunneling magnetoresistance. This can set an upper bound on the thickness of the metal, e.g. Hf or Zr, that is deposited as the precursor step for forming the metal-oxide dusting layer. Experiments have shown that 0.1 nm thickness can yield high tunneling magnetoresistance, of the order of 100% or more if the MgO layer is sufficiently thick, for example about 1.6 nm or more. Thicker metal-oxide dusting layers can be used as appropriate for a particular implementation of the disclosed technology.

For three-terminal magnetic tunnel junction devices that have in-plane magnetic anisotropy and that are switched by the spin-orbit torques generated by the spin Hall effect it is advantageous to be able to vary the value of the interfacial perpendicular magnetic anisotropy energy density (Kₛ) to obtain whatever value of demagnetization field (4πM_{eff}) is optimum for a particular implementation. This is readily achievable with the metal-oxide dusting technique by varying the thickness of the deposited precursor metal. This is demonstrated by the results shown in FIG. 4 as the result of Hf metal dusting of the top of a 1.8 nm in-plane magnetized FeCoB free layer prior to it being oxidized during the deposition of the MgO tunnel barrier and top pinned layer to form a complete three-terminal MTJ device.

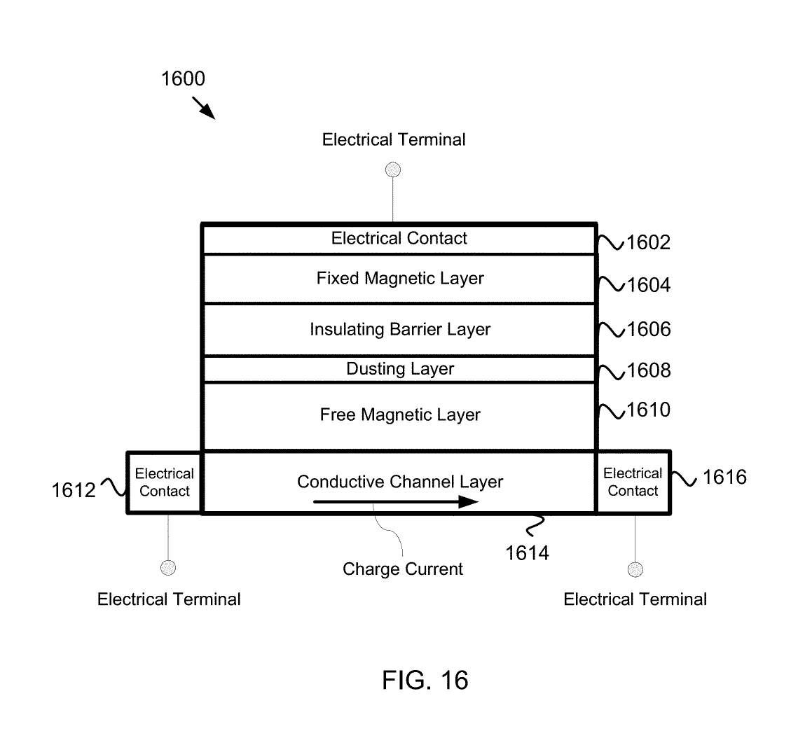

FIG. 16 shows an example of a magnetic tunneling junction (MTJ) device structure 1600 including a conductive channel layer 1614, which exhibits spin Hall effect (SHE), with a dusting layer 1608 disposed between an insulating barrier layer 1606 and a free magnetic layer 1610. The MTJ device structure 1600 implemented based on the disclosed technology may include an electrical contact 1602 in contact with a fixed (pinned) magnetic layer 1604, an insulating barrier layer 1606 formed over the free magnetic layer 1610, the free magnetic layer 1610 formed over the conductive channel layer 1614, and the dusting layer 1608 formed between the insulating barrier layer 1606 and the free magnetic layer 1610. The multiple layers in the MTJ device structure 1600 may have specific selection of the materials and dimensions and be configured to provide a desired interfacial electronic coupling between the free magnetic layer and the conductive channel layer 1614 to allow a large flow of spin-polarized electrons in the conductive channel layer 1614 in response to a given charge current injected into the conductive channel layer 1614 and to provide efficient injection of the generated spin-polarized electrons or charged particles into the free magnetic layer of the MTJ device structure 1600. Two electrical contacts 1612 and 1616 are placed at two locations of the conductive channel layer 1614 and are coupled to a charge current circuit 1618 to supply the charge current to the conductive channel layer 1614. In implementations, the free and fixed (pinned) magnetic layers 1610 and 1604 may have a magnetization that is perpendicular to the layers or a magnetization that is parallel to the layer. The dusting layer 1608 may include a non-magnetic layer, such as hafnium oxide (HfO₂), yttrium oxide (Y₂O₃), zirconium dioxide (ZrO₂), other transition metal oxides such as TiO₂, other rare earth oxides, or a stable metal oxide with high energy of formation similar to or better than HfO₂. The conductive channel layer 1614 may include heavy metal such as FeCoB, FeCo, FeB, or other Fe alloy. For example, the conductive channel layer 1614 may be a FeCoB layer. The insulating barrier layer 1606 may include an oxide layer such as MgO. Although not shown in FIG. 16, the MTJ device structure may further include another insulating layer (e.g., MgO layer) between the free magnetic layer 1610 and the conductive channel layer 1614. Although not shown in FIG. 16, the MTJ device structure 1600 may further include another metal layer such as transition metal layer between the free magnetic layer and conductive channel metal layer. Where the conductive channel metal layer 1614 is formed of heavy metal, this another metal layer may be formed of normal metal.

FIG. 17 shows another example of a magnetic tunneling junction (MTJ) device structure 1700. In an implementation of the disclosed technology, the MTJ device structure 1700 may include a combination of a dusting layer 1708 at an interface between an insulating barrier layer 1706 and a free magnetic layer 1710 and a spacer layer 1712 at an interface between the free magnetic layer 1710 and a conductive channel layer 1716 exhibiting the SHE. The dusting layer 1708 may include a non-magnetic layer, such as hafnium oxide (HfO₂), yttrium oxide (Y₂O₃), zirconium dioxide (ZrO₂), other transition metal oxides such as TiO₂, other rare earth oxides, or a stable metal oxide with high energy of formation similar to or better than HfO₂. For example, the dusting layer 1708 may be a sub-monolayer of HfO₂ or Hf, and the spacer layer 1712 may be a monolayer of Hf. For example, the spacer layer 1712 may be an amorphous Hf layer.

The MTJ device implemented based on the disclosed technology may further include a first electrical contact layer 1702 in contact with the fixed magnetic layer 1704, a second electrical contact 1714 in contact with a first location of the electrically conductive channel layer 1716, and a third electrical contact 1718 in contact with a second location of the electrically conductive channel layer 1716. The MTJ device may further include a MTJ circuit coupled between the first electrical contact and one of the second and third electrical contacts to supply a sensing current or a voltage to the MTJ element, and a charge current circuit coupled between the second and third electrical contacts to supply the in-plane charge current into the electrically conducting magnetic layer structure.

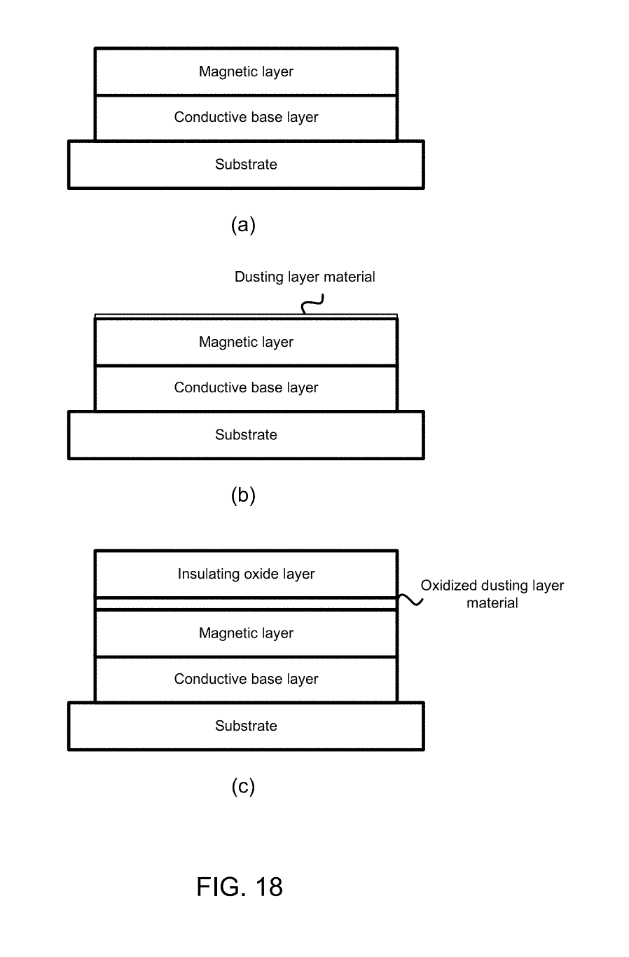

FIGS. 18(a)-18(c) show an example fabrication method of a magnetic structure in accordance with some implementations of the disclosed technology. As shown in FIG. 18(a), the method includes forming, over a substrate, a conductive base layer comprising a conductor material, and forming, over the conductive base layer, a free magnetic layer. As shown in FIG. 18(b), the method includes forming, over the free magnetic layer, one or two atomic layers of dusting layer material. As shown in FIG. 18(c), the one or two atomic layers of dusting layer material may be oxidized while an insulating layer is formed over the one or two atomic layers of dusting layer material through a radio frequency (RF) sputtering deposition. Although not shown in FIG. 18(a)-18(c), additional layers may be formed. For example, a spacer layer may be formed between the conductive base layer and the free magnetic layer, and a fixed magnetic layer may be formed over the insulating layer.

The magnetic structures disclosed in this patent document may include a combination of a magnetic layer and an adjacent non-magnetic dusting layer comprising a metal oxide to use this combination as a composite switchable ferromagnetic material with enhanced PMA. Here, the magnetic layer may be called a PMA magnetic layer. In applications utilizing spin-polarized current, the magnetic layer may be called a free magnetic layer. The material and the thickness of the dusting layer and the spacer layer are selected with respect to the material configurations of the free magnetic layer and the SHE metal layer to enable the interface between the insulating barrier layer and the free magnetic layer to produce PMA, thus enhancing the voltage-controlled magnetic anisotropy effect of the 3-terminal MTJ device.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples are described and other implementations, enhancements and variations can be made based on what is described and illustrated in this patent document.

What is claimed is what is described and illustrated, including:

1. A device, comprising:
a thin-film magnetic structure that includes:
a substrate; and
thin film layers formed over the substrate to include:
a ferromagnetic layer formed over the substrate; and
a non-magnetic dusting layer in contact with the ferromagnetic layer and structured to have a thickness around one molecular layer to enhance an interfacial perpendicular magnetic anisotropy energy density of the ferromagnetic layer.

2. The device as in claim 1, wherein the ferromagnetic layer includes a ferromagnetic material containing Fe as a component to exhibit perpendicular magnetic anisotropy (PMA).

3. The device as in claim 1, wherein the ferromagnetic layer includes a ferromagnetic material containing Fe as a component to exhibit in-plane magnetic anisotropy where an effective demagnetization field is substantially below 4πMₛ where Mₛ is the saturation magnetization of the ferromagnetic layer.

4. The device as in claim 1, wherein the ferromagnetic layer includes FeCoB, FeCo, FeNi, FeMn, FeCr, or FeB.

5. The device as in claim 1, wherein the ferromagnetic layer includes a binary alloy, or tertiary alloy or compound that includes Fe as a component.

6. The device as in claim 1, wherein the non-magnetic dusting layer includes a hafnium oxide, a zirconium oxide, or a titanium oxide.

7. The device as in claim 1, wherein the non-magnetic dusting layer includes a transition metal oxide.

8. The device as in claim 1, wherein the non-magnetic dusting layer includes a rare earth oxide.

9. The device as in claim 1, wherein the non-magnetic dusting layer includes a stable metal oxide with the magnitude of its standard enthalpy of formation similar or greater than HfO₂.

10. The device as in claim 1, wherein the non-magnetic dusting layer includes an oxide of an element that has a particularly large magnitude for the standard enthalpy of formation for the oxide, including europium, yttrium, scandium, or lutetium.

11. The device as in claim 1, wherein the non-magnetic dusting layer includes a binary oxide X_{y}O_{z} where z≥y, that has a higher standard enthalpy of formation than MgO, and with stoichiometry in which there is at least one oxygen ion in the oxide for every metal ion.

12. The device as in claim 1, wherein the thin film layers further comprise a metal layer formed between the substrate and the ferromagnetic layer.

13. The device as in claim 1, wherein the thin film layers further comprise an oxide layer formed on the non-magnetic dusting layer.

14. The device as in claim 1, wherein the thin film layers further comprise a spacer layer disposed between the metal layer and the ferromagnetic layer.

15. The device as in claim 14, wherein the spacer layer includes a monolayer or more of Hf, or a monolayer or more of Zr.

16. The device as in claim 1, wherein:
the thin film layers include a magnetic tunnel junction (MTJ) as a magnetoresistive element that includes the ferromagnetic layer, with the non-magnetic dusting layer in contact with the ferromagnetic layer, that exhibits perpendicular magnetic anisotropy (PMA) or in-plane magnetic anisotropy or a combination thereof as a free magnetic layer whose magnetic orientation direction can be switched or changed; a pinned magnetic layer whose magnetic moment is fixed in direction; and an insulating barrier layer that is between the free magnetic layer and the pinned magnetic layer and is sufficiently thin to allow electrons to transit through the barrier layer via quantum mechanical tunneling.

17. The device as in claim 16, wherein the non-magnetic dusting layer is an oxide dusting layer of a thickness ranging from 0.05 nm to 0.3 nm.

18. The device as in claim 1, wherein:
the thin film layers include a magnetic tunnel junction (MTJ) as a magnetoresistive element that includes a bottom magnetic layer, with the immediately adjacent non-magnetic dusting layer, that exhibits on average perpendicular magnetic anisotropy but also exhibits regions of non-uniform magnetization due to a localized chiral spin structure, wherein the position of the chiral spin structure can be manipulated by a spin current generated by the presence of an underlying heavy metal layer; a top pinned magnetic layer whose magnetic moment is fixed in direction; and an insulating MgO barrier layer that is between the dusted bottom magnetic layer and the top pinned magnetic layer and is sufficiently thin to allow electrons to transit through the barrier layer via quantum mechanical tunneling.

19. The device as in claim 18, wherein the non-magnetic dusting layer is an oxide dusting layer of a thickness ranging from 0.05 nm to 0.3 nm.

20. A method of fabricating a magnetic structure comprising:
forming, over a substrate, a conductive base layer comprising a conductor material;
forming, over the conductive base layer, a magnetic layer;
depositing, over the magnetic layer, a metal layer of a thickness ranging from one atom or molecule to two atoms or molecules immediately adjacent to the magnetic layer;
forming, over the metal layer, an insulating oxide layer; and
causing the metal layer to transform into a non-magnetic dusting layer via oxidation of the metal layer before or during the formation of the insulating oxide layer by exposure to oxygen ions or molecules.

21. The method as in claim 20, wherein the conductive base layer is a spin Hall effect base layer including two laterally separated terminals.

22. The method as in claim 21, wherein the conductive base layer includes tungsten (W), tantalum (Ta), or platinum (Pt), or alloys containing W, Ta or Pt as a component.

23. The method as in claim 20, wherein the oxide layer includes a magnesium oxide (MgO).

24. The device as in claim 20, wherein the magnetic layer includes FeCoB, FeCo, FeNi, FeMn, FeCr, or FeB.

25. The device as in claim 20, wherein the magnetic layer includes a binary alloy, or tertiary alloy or compound that includes Fe as a component.

26. The device as in claim 20, wherein the non-magnetic dusting layer includes a hafnium oxide, a zirconium oxide, or a titanium oxide.

27. The device as in claim 20, wherein the non-magnetic dusting layer includes a transition metal oxide.

28. The device as in claim 20, wherein the non-magnetic dusting layer includes a rare earth oxide.

29. The device as in claim 20, wherein the non-magnetic dusting layer includes a stable metal oxide with the magnitude of its standard enthalpy of formation similar or greater than HfO₂.

30. The device as in claim 20, wherein the non-magnetic dusting layer includes an oxide of an element that has a particularly large magnitude for the standard enthalpy of formation for the oxide, including europium, yttrium, scandium, or lutetium.

31. The device as in claim 20, wherein the non-magnetic dusting layer includes a binary oxide X_{y}O_{z} where z≥y, that has a higher standard enthalpy of formation than MgO, and with stoichiometry in which there is at least one oxygen ion in the oxide for every metal ion.

32. The method as in claim 20, further comprising forming a spacer layer between the conductive base layer and the magnetic layer.

33. The method as in claim 20, further comprising post-fabrication annealing treatments, wherein the non-magnetic dusting layer is used to retain a strong perpendicular magnetic anisotropy (PMA) or a reduced effective demagnetization field even after the post-fabrication annealing treatments.
